(19) United States
(12) Patent Application Publication
(10) Pub. No.: US 2014/0194172 A1
(43) Pub. Date: Jul. 10, 2014

(54) CAPTURE GAME APPARATUS

(71) Applicant: Hasbro, Inc., Pawtucket, RI (US)

(72) Inventors: Dan Klitsner, LARKSPUR, CA (US); Hakan Diniz, Springfield, MA (US)

(73) Assignee: Hasbro, Inc., Pawtucket, RI (US)

(21) Appl. No.: 14/207,103

(22) Filed: Mar. 12, 2014

Related U.S. Application Data
(63) Continuation of application No. PCT/US12/56470, filed on Sep. 21, 2012.
Application No. PCT/US12/56470 is a continuation-in-part of application No. 13/246,108, filed on Sep. 27, 2011.

(51) Int. Cl. A63F 9/24; H05K 13/04

(52) U.S. Cl. CPC A63F 9/24; H05K 13/04
USPC 463/7; 29/825

(57) ABSTRACT

An electronic hand held puzzle game apparatus in which the apparatus includes a housing with left and right housing portions, a first array of lights connected to the left housing portion and a second array of lights fixedly connected to the right housing portion. The first array of lights and the left housing portion is translatable and rotatable relative to the right housing portion, and the first array of lights is movable around an axis extending perpendicular to a housing longitudinal axis. When a puzzle piece light pattern appears on the first array of lights, a player moves that array to align the light pattern with a non-illuminated space on the second array of lights. Closing a compression switch transfers the puzzle piece from the first array of lights to the second array of lights provided that the player's alignment is correct.

### PRIORITY CROSS-REFERENCE TO RELATED APPLICATIONS

This application is a continuation of and claims priority benefit from PCT International Application Publication No. WO 2013/048886 A1, Appl. No. PCT/US12/56470 filed Sep. 21, 2012 and U.S. Application Publication No. 2013/0079074 A1, application Ser. No. 13/246,108 filed Sep. 27, 2011 entitled “Capture Game Apparatus” which is a continuation-in-part thereof, each expressly incorporated herein by reference.

### FIELD OF THE INVENTION

The present invention relates generally to a hand held electronic game apparatus, and, more particularly, in one embodiment, to a capture-the-light hand held electronic game apparatus that illuminates for very short durations one or more of a plurality of light sources that are energized in predetermined sequences; a player is required to “capture” a specific light source by quickly closing a switch to stop the sequence when that specific light source is illuminated, and in another embodiment, to a light pattern game with a hand held electronic puzzle apparatus that features a predetermined light array on one portion of the apparatus and another predetermined light array on a second portion of the apparatus and if those light arrays are compatible and aligned the player is required to close the switch.

### BACKGROUND OF THE INVENTION

Game apparatus that require fast reactive responses by players are fun to play and often very competitive. Such games have been patented in the past but leave room for new games that offer more and/or different challenges and greater excitement. New and fresh features for games are desirable but creating and developing such features in a successful manner have often proven difficult.

As mentioned, hand held electronic games are disclosed in earlier patents as recited below. For example, U.S. Pat. No. 4,261,563 for an “Electronic Time Reaction Game” issued in 1981 to Goldfarb purports to disclose a time reaction game where a microprocessor in an apparatus having two sets of lights, one for each of two players, initiates a game cycle by first generating a ready signal, either from a speaker or from the lights, or both, then delaying for a varying time interval, the interval being unknown to the players, and thereafter generating a start signal, either from the speaker or the lights, or both. The object of the game is to play enough cycles for one player to activate all of the lights of his set of lights before his opponent can activate all of his set of lights. Once the start signal is issued the players attempt to manually depress a response switch before his opponent can do so to win a score. In one embodiment, each player has two response switches from which to choose activation. One switch activates a light from the player's set of lights while the other switch deactivates a light from his opponent's set of lights.

In the same year, U.S. Pat. No. 4,298,198 issued for an “Electronic Game Apparatus For A Single Player or Opposing Players” to Huang and Ling-Huang, and purports to disclose an elongated box with a series of lights, sixteen are shown, and several switches. A switch is depressed to cause one of two lights to glow, the two lights being several lights away from an end of the series of lights. Depending on which light is illuminated, one of the players must depress another switch to energize a streak of lights to begin. Succeeding lights are quickly energized giving the impression that the lights are moving toward one of the ends of the series of lights. The object of the game is to have the players alternately react quickly enough to prevent the streak from energizing the end light nearest him/her such that the light streak moves back and forth between the players. The back and forth streaking will continue until one of the players fails to react quickly enough, whereupon an end light is energized, the game ends, and the other player wins or score a point.

In 1982, a U.S. Patent issued to Breslow and Erickson, U.S. Pat. No. 4,326,710, for a “Talking Electronic Game” purporting to include an integrated circuit voice synthesizer to generate a plurality of first partial phrases, each forming the beginning of a complete phrase, and a plurality of second partial phrases, each forming the end of a complete phrase. The beginning and ending phrases are assigned at random to a plurality of push buttons, and the object of the game is to match up, from memory, the beginning and ending phrases of various complete phrases by appropriate actuation of the various push buttons. The winner is the player who matches all of the partial phrases correctly with the fewest number of incorrect match ups. Another U.S. Pat. No. 4,913,432 issued in 1990 for an “Electromechanical Reaction-Time Game Toy” to Barra, and purports to disclose another reaction type game where a trigger or push button is attached to a drive such as a stretched rubber band mounted in a box. The drive is also attached to pointers movable along marked panels mounted on opposite longitudinal sides of the box. The marks on the panels, which are randomly arranged, serve to indicate values such as numbers or baseball indicia. Depressible stop buttons are also mounted along the sides of the box. The game starts when the trigger is rotated so as to release the rubber band causing the pointers to move quickly along the panels. The player uses the depressible buttons to stop the pointers at a desirable location along the panel in order to achieve the highest number or run score. An electrical embodiment may use a series of lights instead of the pointers to indicate motion along the box.

A year later, Barra received U.S. Pat. No. 5,060,941 for an “Electronic Reaction-Time Game Toy” which operated as the device disclosed in his first mentioned patent but is electronically based. U.S. Pat. No. 5,685,776 issued to Stambolic and others in 1997 for a “Hand-Held Electronic Game Devices,” and purports to disclose hand-held electronic game devices having elongated tubular forms with a centrally mounted electronic displays and various types of controls at either end of the tubes, such as push buttons, pull switches, rotary switches, toggle switches, spring-loaded balls, flip switches, momentary switches, slides switches, twist knobs, mouse controls, pointer balls, and lever arms. The game also includes a computer that is operated by the controls, a display and a speaker. The pull switches include return springs. One embodiment shown in FIG. 6, is a game intended to be held in a horizontal orientation such that the end handles may be twisted and pushed inwards by both hands of a player, allowing the game to be manipulated to effect play. The games disclosed include displays with an amoeba moving through a hostile environment, a shark attempting to “eat” as many fish as possible while avoiding dangerous situations, a man on a pogo stick attempting to save a city from high flying buzzards, various shapes which must be capture and correctly united, a motocross moving across while avoiding obstacles, and a martial arts fighter and his opponents.

In 2000, Klitsner and Welch were issued U.S. Pat. No. 6,086,478 for a “Hand-Held Voice Game” purporting to disclose a game device having an elongated housing with a controller, a speaker and three different input switches, a pressure switch pressed by a player, a pull knob and a twist knob. The game starts with an audible signal that relates to one of the input switches. After actuation of the selected input switch, the controller will issue a second audible signal relating to one of the three switches that must be actuated by the player within a predetermined time. If the player is successful the game goes on. If the player does not actuate the correct switch within the allotted time an error signal is issued. Another patent issued to Klitsner a year later, U.S. Pat. No. 6,210,278, also entitled “Hand-Held Voice Game”. This second patent is a continuation-in-part of his 2000 patent and additionally discloses a game with two curved handles, a controller, a speaker and five input devices, a pressure switch, a pull knob, a twist knob, a spin switch and a lever switch. The game is played as described for the device in his 2000 patent. A third U.S. Patent issued to Klitsner, along with Clemens and Levenberg, in 2006, U.S. Pat. No. 7,044,857, is for a “Hand-Held Musical Game” in which the game apparatus is formed as a stylized guitar with a body portion and a neck portion. The neck portion is rotatable relative to the body portion, the body portion includes a strum bar, and there is a slide element movable along the neck portion. Electronics are in the apparatus to provide audio and/or visual instructions to a player to rotate the neck portion, move the slide element or manipulate the strum bar in a predetermined period of time.

All of the game apparatus mentioned above are of interest but none of them disclose the structure of the present invention nor do they provide the play value of the invention described in detail below.

### SUMMARY OF THE INVENTION

In accordance with the present invention, advantageous methods and apparatus are disclosed in the form of light pattern games for either “capturing a moving light” or comparing puzzle patterns on two portions of the apparatus. In the capture version, the “light,” one of a series of momentarily illuminated light sources, is “moved” by a controller, such as a programmed microprocessor and ancillary electronics, in predetermined sequences or patterns. Each pattern is created by having the light sources individually illuminate or energize, but only for short predetermined durations, at predetermined tempos. A player of the game must react quickly and stop the sequence when a light source at a predetermined specific location is momentarily energized. The game apparatus is held in a player's hands so that he/she is able to view all of the light sources. Stopping the light sequence successfully requires that the concentrating player quickly activate a switch by squeezing the apparatus. In the comparing patterns version the game may be thought of as an electronic puzzle game where a light pattern appearing on a first array of lights must be matched to the same pattern on a second array of lights where the pattern may appear as non-illuminated lights, or dark spaces. The game apparatus also have the advantages of being relatively simple, fun to use, safe, relatively inexpensive, compact and yet, structurally robust.

Briefly summarized, the present invention relates to a light pattern game apparatus including a housing having first and second portions, a first array of lights mounted to the first portion of the housing, a second array of lights mounted to the second portion of the housing, a controller connected to the housing and. to the first and second arrays of lights for selecting from a multiplicity of varying patterns for display on the first and second arrays of lights, including a first predetermined light pattern to appear on the first array of lights and a second predetermined pattern to appear on the second array of lights, a compression switch mounted to the housing operatively connected to the first and second arrays of lights and to the controller for activation when the patterns of the first and second arrays of lights respectively display the first and the second predetermined patterns, and an indicator structure mounted to the housing and operatively connected to the controller and the compression switch for informing a game player whether the compression switch is activated when the first and the second predetermined. patterns are displayed on the first and second arrays of lights.

The invention also relates to a method for making a puzzle game apparatus, the steps of the method including providing a housing having first and second portions, each portion being structurally arranged to translate relative to one another along a longitudinal axis of the housing, mounting a first array of lights to the first portion of the housing to enable the first array of lights to rotate around the longitudinal axis of the housing and to rotate around an axis perpendicular to the longitudinal axis, mounting a second array of lights to the second. portion of the housing, connecting a controller to the housing and to the first and second arrays of lights for selecting from a multiplicity of varying light patterns for display on the first and second arrays of lights, including a first predetermined light pattern to appear on the first array of lights and a second predetermined pattern to appear on the second array of lights, connecting a compression switch to the first and second arrays of lights and to the controller for activation when the patterns of the first and second arrays of lights display the first and the second predetermined patterns, and mounting au indicator ,structure to the housing and operatively connecting the indicator structure to the controller and the compression switch.

### BRIEF DESCRIPTION OF THE DRAWINGS

For the purpose of facilitating an understanding of the invention, the accompanying drawings and detailed description illustrate preferred embodiments thereof, from which the invention, its structures, its construction and operation, its processes, and many related advantages may be readily understood and appreciated.

FIG. 1 is a front elevation view of a preferred embodiment of the present invention in the form of a hand held electronic game apparatus.

FIG. 2 is a rear elevation view of the game apparatus shown in FIG. 1, with open handles to show internal features.

FIG. 3 is a rear elevation view of the game apparatus shown in FIG. 2, with an open housing.

FIG. 4 is an enlarge view of the left hand handle shown in FIGS. 2 and 3.

FIG. 5 is an isometric view of an alternative embodiment of the present invention, partially diagrammatic, and in an extended position.

FIG. 6 is an isometric view of the alternative embodiment shown in FIG. 5, in a capture-the-light position.

FIG. 7 is a flow diagram for a method of making the embodiment of the inventive game apparatus shown in FIG. 1.

FIG. 8 is downward looking perspective view of another embodiment of the present invention illustrating a hand held puzzle game apparatus having a housing and first and second arrays of lights.

FIG. 9 is an upward looking perspective view of the game apparatus shown in FIG. 8.

FIG. 10 is a top plan view of the game apparatus shown in FIGS. 8 and 9.

FIG. 11 is a side elevation view of the game apparatus shown in FIGS. 8-10.

FIG. 12 is a side elevation view of the game apparatus shown in FIGS. 8-11.

FIG. 13 is a downward looking perspective view of the game apparatus shown in FIGS. 8-12, with the first and second arrays of lights removed.

FIG. 14 is an enlarged perspective view of a portion of the game apparatus shown in FIGS. 8-12, with a cover removed from a first portion of the housing.

FIG. 15 is a longitudinal cross section perspective view taken along line 15-15 of FIG. 12.

FIG. 16 is a longitudinal cross section perspective view taken along line 16-16 of FIG. 12.

FIG. 17 is a diagrammatic plan view, depicted in a planar arrangement, of the first array of lights shown in FIG. 10.

FIG. 18 is a diagrammatic plan view, depicted in a planar arrangement, of the second array of lights shown in FIG. 10.

FIG. 19 is an outline of a puzzle piece consisting of a single light source of the arrays of lights and is referred to as a small square piece hereinbelow.

FIG. 20 is an outline of a puzzle piece consisting of two aligned light sources of the arrays of lights in a rectangular format and is referred to as a rectangle piece hereinbelow.

FIG. 21 is an outline of a puzzle piece consisting of two misaligned or diagonally aligned light sources of the arrays of lights and is referred to as a bowtie piece hereinbelow.

FIG. 22 is an outline of a puzzle piece consisting of three light sources of the arrays of lights in a right angle format and is referred to as an angle piece hereinbelow.

FIG. 23 is an outline of a puzzle piece consisting of four light sources of the arrays of lights in a square format and is referred to as a large square hereinbelow.

FIG. 24 is a plan view of the first and second arrays of lights as shown in FIGS. 17 and 18, illustrating a rectangle puzzle piece illuminated in the first array of lights and a dark rectangle puzzle space in the second array of lights.

FIG. 25 is a plan view similar to that shown in FIG. 24, where the rectangle puzzle piece is aligned with the dark rectangle puzzle space.

FIG. 26 is a plan view similar to that shown in FIG. 25, where the first and second arrays of lights are brought together to cause the puzzle piece to “transfer” from the first array of lights to the second array of lights.

FIG. 27 is a plan view similar to that shown in FIG. 26, where the puzzle piece has been transferred and the previously illuminated rectangle puzzle piece of the first array of lights is dark and the previously dark rectangle puzzle space of the second array of lights is illuminated.

FIG. 28 is a plan view of the first and second arrays of lights illustrating a small square puzzle piece illuminated in the first array of lights and a dark small square puzzle space in the second array of lights at the lower right corner.

FIG. 29 is a plan view similar to that shown in FIG. 28, where the small square puzzle piece is aligned with the dark small square puzzle space.

FIG. 30 is a plan view similar to that shown in FIG. 29, where the first and second arrays of lights are brought together to cause the puzzle piece to transfer electronically from the first array of lights to the second array of lights.

FIG. 31 is a plan view similar to that shown in FIG. 30, where the puzzle piece has been transferred and the previously illuminated small square puzzle piece of the first array of lights is dark and the previously dark small square puzzle space of the second array of lights is illuminated because a game rule provides that the puzzle piece is able to move through dark spaces in both arrays of lights.

FIG. 32 is a plan view of the first and second arrays of lights illustrating a bowtie puzzle piece illuminated in the first array of lights and a dark large square puzzle space in the second array of lights at the lower right side.

FIG. 33 is a plan view similar to that shown in FIG. 32, where the bowtie puzzle piece is aligned with the dark puzzle space.

FIG. 34 is a plan view similar to that shown in FIG. 33, where the first and second arrays of lights are brought together to cause the puzzle piece to transfer from the first array of lights to the second array of lights.

FIG. 35 is a plan view similar to that shown in FIG. 34, where the puzzle piece has been transferred and the previously illuminated bowtie puzzle piece of the first array of lights is dark and a previously dark bowtie puzzle space of the second array of lights is illuminated.

FIG. 36 is a plan view of the first and second arrays of lights illustrating a bowtie puzzle piece illuminated in the first array of lights and several dark puzzle spaces in the second array of lights.

FIG. 37 is a plan view similar to that shown in FIG. 36, where the bowtie puzzle piece has been moved in an attempt to align the bowtie puzzle piece with some of the dark puzzle spaces.

FIG. 38 is a plan view similar to that shown in FIG. 37, where the first and second arrays of lights are brought together to attempt a transfer of the bowtie puzzle piece from the first array of lights to the second array of lights.

FIG. 39 is a plan view like that shown in FIG. 38, where the bowtie puzzle piece has been unable to be transferred because of an obstacle in the lower right corner of the second array of lights.

FIG. 40 is a plan view of the first and second arrays of lights illustrating a bowtie puzzle piece illuminated in the first array of lights and dark puzzle spaces in the second array of lights identical to the view of the second array of lights in FIG. 36.

FIG. 41 is a plan view similar to that shown in FIG. 40, where the bowtie puzzle piece has been moved to partially align with the dark puzzle spaces.

FIG. 42 is a plan view illustrating the first array of lights being twisted clockwise to cause the first array of lights to rotate 90° .

FIG. 43 is a plan view similar to that shown in FIG. 41, where the bowtie puzzle piece is fully aligned with a dark bowtie puzzle space.

FIG. 44 is a plan view similar to that shown in FIG. 43, where the first and second arrays of lights are brought together to attempt a transfer of the puzzle piece from the first array of lights to the second array of lights.

FIG. 45 is a plan view similar to that shown in FIG. 44, where the puzzle piece has been successfully transferred and the previously illuminated bowtie puzzle piece of the first array of lights is dark and the previously dark bowtie puzzle space of the second array of lights is illuminated.

FIG. 46 is a plan view of the first and second arrays of lights illustrating a rectangle puzzle piece illuminated in the first array of lights and a dark rectangle puzzle space in the second array of lights.

FIG. 47 is a plan view similar to that shown in FIG. 46, where the rectangle puzzle piece is aligned with the dark rectangle puzzle space by “overhanging” the border of the second array of lights.

FIG. 48 is a plan view similar to that shown in FIG. 47, where the first and second arrays of lights are brought together to cause the puzzle piece to transfer from the first array of lights to the second array of lights.

FIG. 49 is a plan view similar to that shown in FIG. 48, where the puzzle piece has been transferred and the previously illuminated rectangle puzzle piece of the first array of lights is dark and the previously dark rectangle puzzle space of the second array of lights is illuminated.

FIG. 50 is a plan view of the first and second arrays of lights illustrating two puzzle pieces illuminated in the first array of lights, a rectangle puzzle piece of a first color and a small square puzzle piece of a second color, and dark puzzle spaces in the second array of lights matching the two puzzle pieces.

FIG. 51 is a plan view similar to that shown in FIG. 50, where the rectangle puzzle piece of the first color is aligned and brought together with the second array of lights to transfer the rectangle puzzle piece and illustrating a game rule that the puzzle piece of the first color must be handled first.

FIG. 52 is a plan view similar to that shown in FIG. 51, where the rectangle puzzle piece has been transferred and the previously illuminated rectangle puzzle piece of the first array of lights is dark and the previously dark rectangle puzzle space of the second array of lights is illuminated.

FIG. 53 is a plan view similar to that shown in FIG. 50, where the small square puzzle piece of the second color is aligned with the second array of lights by overhanging the border of the second array of lights.

FIG. 54 is a plan view similar to that shown in FIG. 53, where the first and second arrays of lights are brought together to transfer the small square puzzle piece from the first array of lights to the second array of lights.

FIG. 55 is a plan view similar to that shown in FIG. 54, where the puzzle piece has been transferred and the previously illuminated small square puzzle piece of the first array of lights is dark and the previously dark small square puzzle space of the second array of lights is illuminated.

FIG. 56 is a plan view of the first and second arrays of lights illustrating two puzzle pieces illuminated in the first array of lights, an angle puzzle piece of a first color and a small square puzzle piece of a second color, and dark puzzle spaces in the second array of lights matching the two puzzle pieces and illustrating that the angle puzzle piece is aligned with spaces of the second array of lights.

FIG. 57 is a plan view similar to that shown in FIG. 56, where the first and second arrays of lights are brought together to transfer the angle puzzle piece.

FIG. 58 is a plan view similar to that shown in FIG. 57, where the angle puzzle piece has been transferred by “passing through” the small square puzzle piece of the second color and the previously illuminated angle puzzle piece of the first array of lights is dark and the previously dark angle puzzle space of the second array of lights is illuminated, and illustrating a game rule that the puzzle piece of the first color is able to pass through the puzzle piece of the second color.

FIG. 59 is a plan view similar to that shown in FIG. 58, where the small square puzzle piece is aligned with the second array of lights by overhanging the border of the second array of lights.

FIG. 60 is a plan view similar to that shown in FIG. 59, where the first and second arrays of lights are brought together to transfer the small square puzzle piece from the first array of lights to the second array of lights.

FIG. 61 is a plan view similar to that shown in FIG. 60, where the second puzzle piece has been transferred and the previously illuminated small square puzzle piece of the first array of lights is dark and the previously dark small square puzzle space of the second array of lights is illuminated.

FIG. 62 is a plan view of the first and second arrays of lights illustrating one angle puzzle piece and one small square, flashing “bomb” in the first array of lights, and a rectangle dark puzzle space in the second array of lights, a space that does not match the angle puzzle piece.

FIG. 63 is a plan view similar to that shown in FIG. 62, where the bomb piece is aligned to create a space in the second array of lights, and the first and second arrays of lights are brought together to transfer the bomb.

FIG. 64 is a plan view similar to that shown in FIG. 63, where the bomb piece has been transferred and the previously flashing small square piece of the first array of lights is dark and a previously illuminated small square space of the second array of lights is flashing before it goes dark thereby creating a space.

FIG. 65 is a plan view similar to that shown in FIG. 64, where the small square illuminated piece of the second array of lights, where the bomb landed, is dark and the angle puzzle piece is aligned with an angle space.

FIG. 66 is a plan view similar to that shown in FIG. 65, where the first and second arrays of lights are brought together to cause the angle puzzle piece to transfer from the first array of lights to the second array of lights.

FIG. 67 is a plan view similar to that shown in FIG. 66, where the angle puzzle piece has been transferred and the previously dark angle puzzle space of the second array of lights is illuminated.

FIG. 68 is a plan view of the first and second arrays of lights illustrating three flashing bombs in an angle pattern in the first array of lights, and fully illuminated puzzle spaces in the second array of lights where the object of play is to make the second array of lights go dark.

FIG. 69 is a plan view similar to that shown in FIG. 68, where the three bombs are aligned to create an angle space and brought together with the second array of lights to transfer the bombs.

FIG. 70 is a plan view similar to that shown in FIG. 69, where the bombs has been transferred and the previously flashing three bombs of the first array of lights are dark and the previously illuminated angle space of the second array of lights is flashing before the angle goes dark.

FIG. 71 is a plan view where the angle of flashing lights is dark in the second array of lights, and the first array of lights shows a second piece, a bowtie of bombs.

FIG. 72 is a plan view similar to that shown in FIG. 71, where the bowtie of bombs is aligned with the second array of lights.

FIG. 73 is a plan view similar to that shown in FIG. 72, where the first array of lights is brought together with the second array of lights to enable the bowtie of bombs to transfer from the first array of lights to the second array of lights.

FIG. 74 is a plan view similar to that shown in FIG. 73, where the bowtie of bombs has been transferred and the previously flashing bombs of the first array of lights are dark and the previously illuminated bowtie spaces of the second array of lights are flashing.

FIG. 75 is a plan view similar to that shown in FIG. 74, where the bowtie of flashing lights is dark in the second array of lights, and the first array of lights show a third piece, a small square, flashing bomb.

FIG. 76 is a plan view similar to that shown in FIG. 75, where the small square bomb is aligned with the second array of lights and the arrays of lights are brought together to transfer the small square bomb from the first array of lights to the second array of lights.

FIG. 77 is a plan view similar to that shown in FIG. 76, where the first array of lights is dark and the flashing bomb is in the second array of lights.

FIG. 78 is a plan view similar to that shown in FIG. 77, where the small square of flashing light in the second array of lights is dark, and the first array of lights show a fourth piece, a rectangle of bombs.

FIG. 79 is a plan view similar to that shown in FIG. 78, where the rectangle of bombs is aligned with the second array of lights.

FIG. 80 is a plan view similar to that shown in FIG. 79, where the first array of lights is brought together with the second array of lights to transfer the rectangle of bombs from the first array of lights to the second array of lights.

FIG. 81 is a plan view similar to that shown in FIG. 80, where the first array of flashing lights is dark and the second array of lights show a flashing rectangle of bombs.

FIG. 82 is a plan view similar to that shown in FIG. 81, where both arrays of lights are dark and the result is a “blackout” of the second array of lights.

FIG. 83 is a plan view identical to that shown FIG. 68, but illustrating a special rule applying to angle bomb pieces, where the angle piece is aligned with a single light source making first contact with the second array of lights.

FIG. 84 is a plan view identical to that shown in FIG. 69, where the first and second arrays of lights are brought together to transfer the bombs.

FIG. 85 is a plan view identical to that shown in FIG. 70, where the bombs have been transferred and the previously flashing three bombs of the first array of lights are dark and the previously illuminated angle space of the second array of lights is flashing.

FIG. 86 is a plan view similar to that shown in FIG. 83, but illustrating the angle bomb piece with two light sources making first contact with the second array of lights.

FIG. 87 is a plan view similar to that shown in FIG. 86, where the first and second arrays of lights are brought together to attempt a transfer of the bombs.

FIG. 88 is a plan view similar to that shown in FIG. 87, showing a partial transfer of the angle bomb, namely, only the first two contacting bombs.

FIG. 89 is a plan view similar to that shown FIG. 86, illustrating a special rule that applies to angle bombs where there is a dark space in the second array of lights.

FIG. 90 is a plan view similar to that shown in FIG. 89, where the first and second arrays of lights are brought together to transfer the bombs.

FIG. 91 is a plan view similar to that shown in FIG. 90, showing that a full transfer of the three-bomb angle is made to the second array of lights.

FIG. 92 is a plan view similar to that shown FIG. 89, and illustrating a special rule that apply to angle pieces.

FIG. 93 is a plan view similar to that shown in FIG. 90, where the first and second arrays of lights are brought together to transfer the bombs.

FIG. 94 is a plan view similar to that shown in FIG. 91, showing that a full transfer of the angle piece is successful.

FIG. 95 is a plan view illustrating a special rule that applies to a two-bomb bowtie where there is no dark space in the second array of lights at the contact location.

FIG. 96 is a plan view similar to that shown in FIG. 95, showing the first and second arrays of lights brought together to attempt a transfer of the bombs.

FIG. 97 is a plan view similar to that shown in FIG. 96, showing that a partial transfer of the bowtie bomb occurred.

FIG. 98 is a plan view illustrating another special rule that applies to a two-bomb bowtie where there is a dark space in the second array of lights at the contact location.

FIG. 99 is a plan view similar to that shown in FIG. 98, illustrating an alignment of the first and second arrays of lights and the first and second arrays of lights brought together.

FIG. 100 is a plan view similar to that shown in FIG. 99, showing that a complete transfer of the bowtie bomb occurred.

FIG. 101 is a plan view illustrating a small square bomb in the first array of lights and a dark space in the second array of lights.

FIG. 102 is a plan view similar to that shown in FIG. 101, where the first and second arrays of lights are brought together.

FIG. 103 is a plan view similar to that shown in FIG. 102, showing that a transfer of the small square bomb was successful.

FIG. 104 is a plan view illustrating a rectangle bomb.

FIG. 105 is a plan view similar to that shown in FIG. 104, illustrating the first and second arrays of lights brought together.

FIG. 106 is a plan view similar to that shown in FIG. 105, showing that a transfer of the rectangle bomb has occurred.

FIG. 107 is a plan view illustrating a three-bomb angle in the first array of lights and the second array of lights having an illuminated rectangle space.

FIG. 108 is a plan view similar to that shown in FIG. 107, illustrating an alignment of the angle bomb in an overhang position.

FIG. 109 is a plan view similar to that shown in FIG. 108, illustrating the first and second arrays of lights brought together.

FIG. 110 is a plan view similar to that shown in FIG. 109, showing a partial transfer of only two of the three-bomb angle.

FIG. 111 is a flow diagram for a method of making the embodiment of the inventive game apparatus shown in FIG. 8.

### DESCRIPTION OF THE PREFERRED EMBODIMENTS

The following description is provided to enable those skilled in the art to make and use the described embodiments set forth in the best mode contemplated for carrying out the invention. Various modifications, equivalents, variations, and alternatives, however, will remain readily apparent to those skilled in the art. Any and all such modifications, variations, equivalents, and alternatives are intended to fall within the spirit and scope of the present invention.

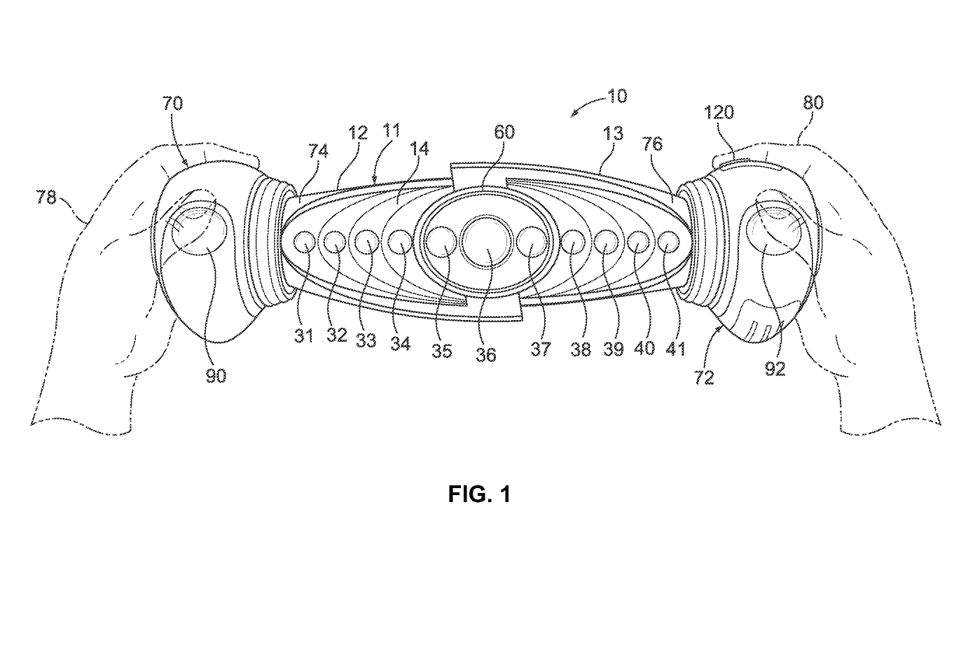

Referring now to FIGS. 1-3, there is shown a preferred embodiment of the present invention in the form of a hand-held electronic game apparatus 10 in which a player wins or moves toward winning by “capturing” a light. The game apparatus may include an elongated housing and two handles mounted at opposite ends of the housing. The housing includes a plurality of individual light sources that may be the eleven light sources, as shown. The game apparatus momentarily energizes or illuminates the individual light sources in predetermined sequences, and the object of the games played on the apparatus is for a player to quickly push the handles inward toward the housing to cause an operating sequence to stop at a predetermined light source when that light source is illuminated. If the illuminated light source is located at the desired location, a player is rewarded. If the light source illuminated when the sequence is interrupted is not at the desired location, the player is deemed to be unsuccessful and he/she receives no reward.

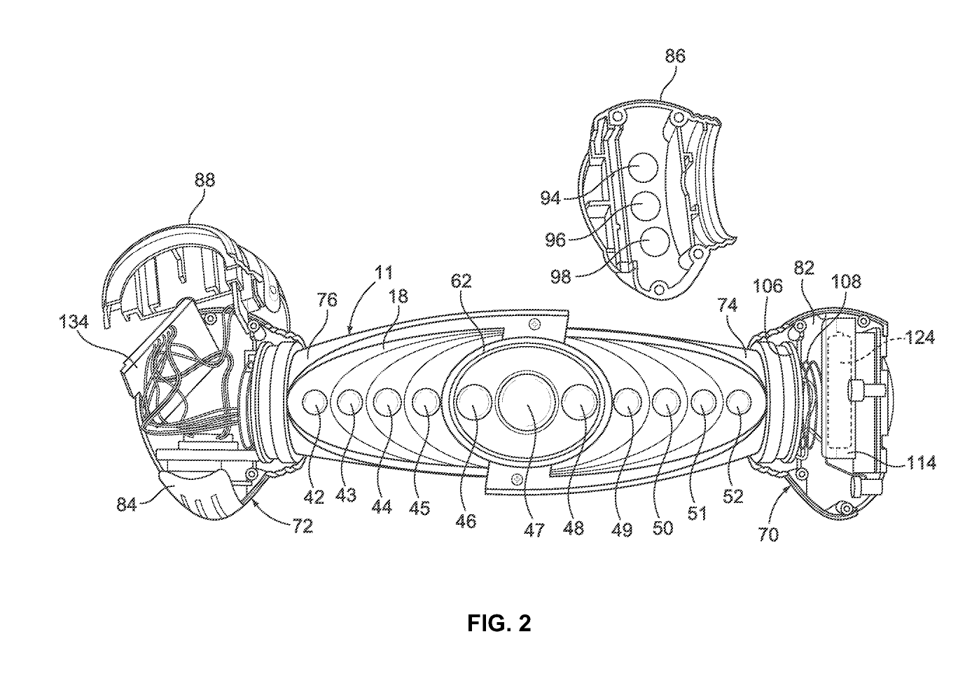

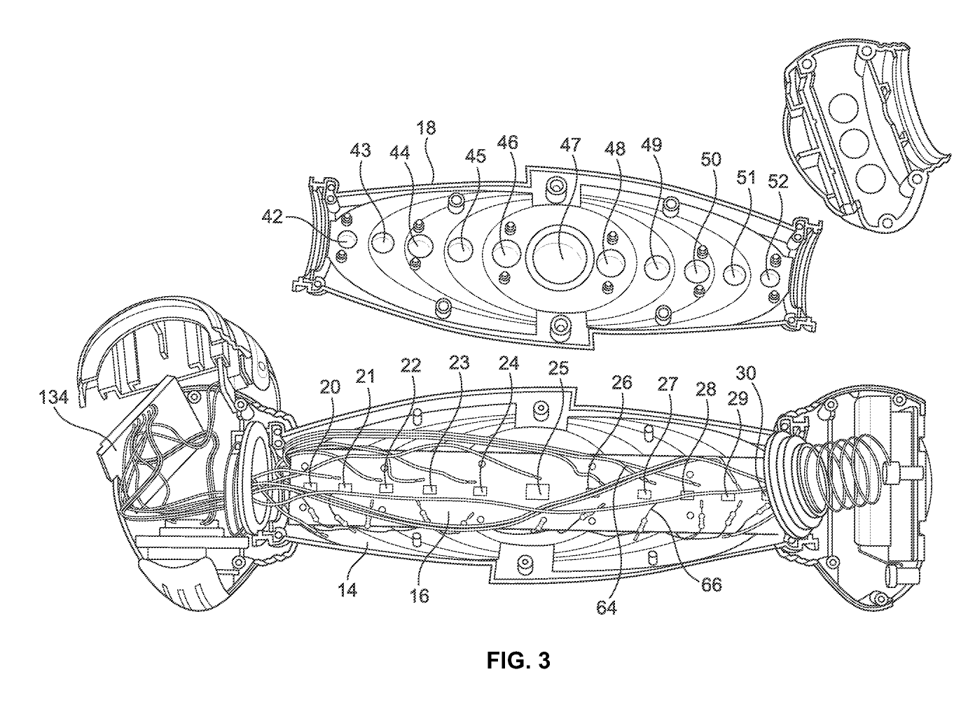

The housing 11 of the capture-the-light game apparatus 10 is elongated and may be divided into first and second portions 12, 13. The housing is stylistically designed and includes a front panel 14, a light bar 16, and a back panel 18. Mounted to the light bar 16 are a plurality of light sources, such as the eleven light sources 20, 21, 22, 23, 24, 25, 26, 27, 28, 29, 30, shown in FIG. 3. The light sources may be divided into two arrays of lights, a first array of lights including the left side light sources 20, 21, 22, 23, 24 in the first portion of the 12 of the housing and a second array of lights including the right side light sources 26, 27, 28, 29, 30 in the second portion 13 of the housing. The light sources are arranged in an extended arrangement and may be linearly displayed. Each light source may include a light emitting diode (LED) and each light source may also include a spherical diffuser, such as the diffusers 31, 32, 33, 34, 35, 36, 37, 38, 39, 40, 41, FIG. 1, mounted to the front panel 14, and the diffusers 42, 43, 44, 45, 46, 47, 48, 49, 50, 51, 52, FIG. 3, mounted to the back panel 18. The diffusers cause light from illuminated sources to appear as a relatively large balls of light to a player or viewer of the game apparatus. The center light source 25 may have a blue color and the other light sources may have a yellow color to indicate that the blue light source is the most desired location for a player to stop an operating light sequence, provided that the blue light source is illuminated at the time. Illumination of the blue light source may be considered an indicator structure for informing a game player whether the player has stopped the light sequence correctly. Of course, a failure of illumination of the blue light source when the player stops the light sequence may also be an indicator structure. The housing 12 may be made of molded plastic and have an oval structure 60, 62 formed in the center of each panel 14, 18. Each oval structure 60, 62, FIGS. 1 and 2, may enclose a “capture zone” formed of the center light source 25 and the two light sources 24, 26, adjacent the center light source. All three light sources may be desired as stopping objectives but the adjacent light sources 24, 26 may be less desired than the center light source 25. Each light source is connected by wires, such as the wires 64, 66 from the light source 27, FIG. 3, to other elements in the apparatus as will be described in detail below.

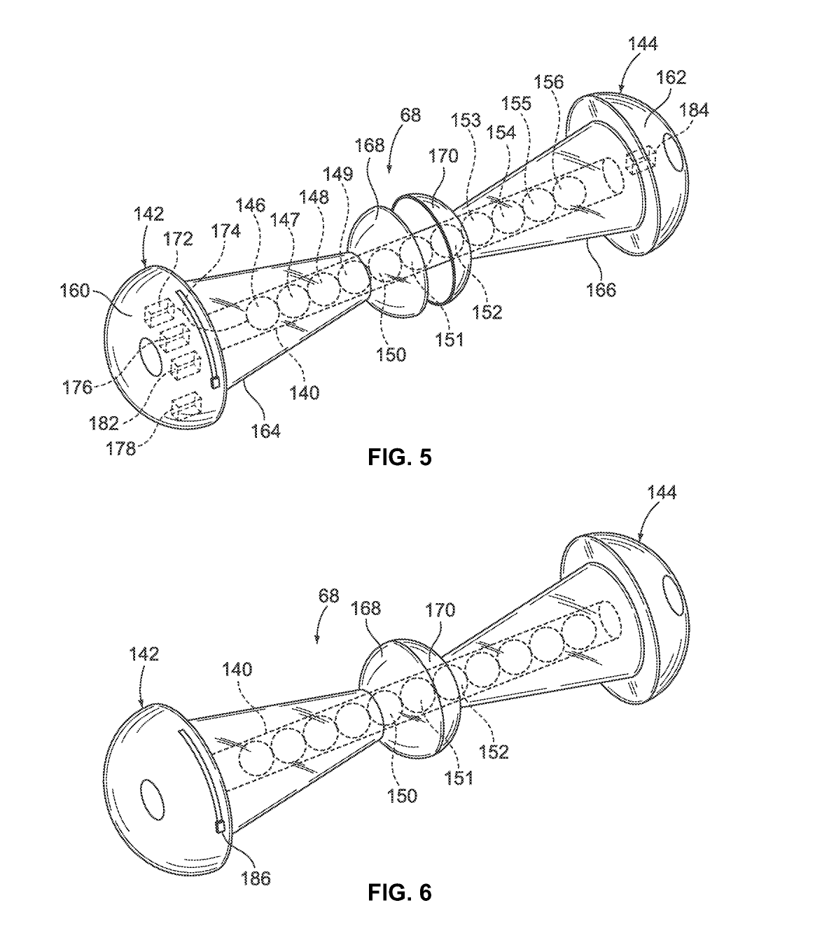

In the alternative, the game apparatus may be styled differently, such as for example the game apparatus 68 shown in FIGS. 5 and 6. Also in the alternative, the arrangement of the light sources may be, for example, laid out in a curve or offset, such as in a saw-tooth pattern. Other light sources may be used instead of LEDs, and different colors may be chosen, or all of the light sources may be the natural color of the source being used.

In the games that may be played on the apparatus 10, detailed below, a player must capture the “moving light” when one of the three light sources in the capture zone ovals is illuminated. The moving light is created by illuminating the LEDs in predetermined sequences or patterns to create the illusion of light motion along the row of eleven LEDs. While no LED actually moves there is the perception of light movement back and forth along the housing when in fact the light sources are individually and momentarily energized in predetermine sequences with each light source being energized for a very short predetermined duration and at a predetermined tempo.

First and second handles 70, 72 may be movably connected to the housing 12 at opposite housing end portions 74,76. The handles are rounded, somewhat tear shaped, and sized so as to be easily and comfortably gripped by a player's hands 78, 80, as shown in phantom lines in FIG. 1. Each handle 70, 72 may also be formed of molded plastic in two parts, such as a front part 82, FIG. 2, of the handle 70 and a front part 84 of the handle 72. Each handle may also include a back part, such as the back part 86 of the handle 70 and the back part 88 of the handle 72. Slight depressions, such as thumb depressions 90, 92, FIG. 1, in the front parts 82, 84 of the handles 70,72, respectively, may be used to facilitate hand placement. Other depressions, such as the depressions 94, 96, 98, FIG. 2, seen from inside the handle back part 86 may be provided for fingers to be positioned once the thumbs of each hand is situated. Similar finger depressions (not shown) may be provided in the handle back part 88. The game apparatus 10 may be held in front of a player's chest, either while the player is standing or seated, using both hands so that he/she may easily see all of the light sources and yet freely swing his/her arms in rhythm to the tempo of the light sequences, if desired.

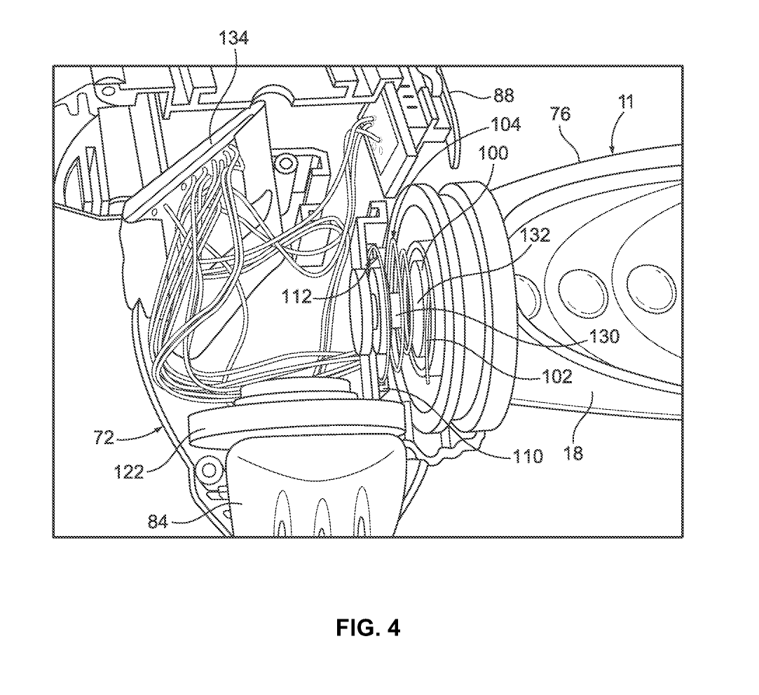

Mounted to the housing end portion 76 is a spring seat 100, FIG. 4, for locating one end 102 of a first biasing element in the form of a compression spring 104. Mounted to the housing end portion 74 is another spring seat 106, FIG. 2, for locating one end of a second biasing element in the form of another compression spring 108. Located in the handle 72 is a spring seat 110, FIG. 4, for locating an opposite end 112 of the first compression spring 104, and located in the handle 70 is a battery compartment 114, FIG. 2, for locating an opposite end of the compression spring 108. The handles 70, 72 are mounted to the end portions 74, 76 of the housing 12 to enable the handles to move toward the housing and against the biasing forces of the springs 104, 108. The handle 72 may also mount a game selector and volume control button 120, FIG. 1. The multifunction button 120 may operate by being moved one way to act as a game selection switch, and by being moved the other way to step through three volume levels for a speaker 122, FIG. 4. Three batteries, such as the battery 124, may be used in the battery compartment to act a power source for the game apparatus.

Mounted in the handle 72 may be a switch actuator 130, FIG. 4, movable toward the housing 12 with the handle to press against a compression switch 132 mounted to the housing when a player desires to stop a light sequence in order to “capture the light.” The handle 72 may also mount a controller 134, such as a microprocessor on a printed circuit board, well known to those skilled in the art, for controlling the game apparatus. The controller may also control the speaker 122 mounted in the handle 72 for generating electronic sounds and speech. The speaker may present a voice with an attitude. The voice may introduce a game, announce scores, and provide reactions to a player's successes and failures. The battery compartment 114, and thus the power source, is operatively connected to the switches 120, 132, the speaker 122, the printed circuit board 134, and the light sources 20, 21, 22, 23, 24, 25, 26, 27, 28, 29, 30 in a manner well known to those skilled in the art. When the game apparatus is sleeping, activation of compression switch 132 wakes the apparatus to start a new game. After a player operating the button 120 selects a game, activating the compression switch 132 may be used to confirm the game choice. Each game continues in a loop until the compression switch is activated. When the handles 70, 72 are brought toward each other, the compression switch 132 closes and the light sequence terminates, and the controller determines whether the player is rewarded and the manner in which the game proceeds. Each game loop may continue for twenty repetitions at which time the controller may treat the game as if the player failed to capture the light.

An indicator structure mounted to the housing 11 and operatively connected to the controller 134 and the compression switch 132 for informing a game player whether the compression switch is activated when the sequence of lights is stopped at the center or adjacent light sources 24, 25, 26, may include the compression switch, the controller and the illuminated light source when the sequence is interrupted and/or the speaker 122 emitting a specific tune and/or appropriate words.

In the alternative, and again referring to FIGS. 5 and 6, another embodiment of the game apparatus is illustrated. The variant game apparatus 68 includes a housing 140 in the form of a light bar, shown in dotted lines, and opposing handles 142, 144. The light bar includes eleven light sources 146, 147, 148, 149, 150, 151, 152, 153, 154, 155, 156 to enable a “ball of light” to move back and forth along the light bar with a predetermined illumination duration and tempo. Each handle 142, 144 includes a semi- spherical handgrip 160, 162, a conically shaped arm 164, 166 and a cup shaped end portion 168, 170 that defines a capture zone when brought together as shown in FIG. 6. A controller 172, wires 174, a compression switch 176, a speaker 178 and biasing elements 182, 184 may be mounted within the handles and housing in a manner similar to that described for the embodiment shown in FIGS. 1-4. A game selector and volume control button 186 is shown as part of the handle 142. To capture a light successfully, the player must push the handles toward each other causing the cup like end portions 168, 170 to come together. The sphere shape formed by the end portions encloses the three light sources 150, 151, 152. If one of the three light sources is illuminated when the player pushes the handles together the player is successful, although capturing the center light source 151 may be more successful than capturing the light sources 150 or 152. If another light source is illuminated when the compression switch 176 is closed the player has failed.

As mentioned above, the object of the game that is played on the hand held electronic game apparatus is to capture the “light” at a preselected location on the light bar. For the games described in detail below, that pre-selected location is the capture zone within the ovals 60, 62, FIGS. 1 and 2. The game apparatus 10 is a game of skill and action that gives the illusion of a light moving along the row of eleven LEDs. For example, the game apparatus may be programmed to have each light source energized momentarily in a predetermined sequence from the light source 20 across the housing to the light source 30 and back again at a predetermined velocity, over and over again. The player is able to view the light sources and follow the predetermined sequence back and forth across the game apparatus, the pattern of on-and-off light sources appearing to the player as a ball of light moving across the game apparatus. The player may also hear a tune from the speaker timed to the light sequence which will allow him to sync his mind and body so as to attempt a “capture the light,” that is, closing the compression switch 132 such that the light source illuminated at the moment the switch is closed is within the ovals.

If the compression switch is closed after the center light source 25 is illuminated and before it is de-energized, the player is most successful and the indicator structure is activated with congratulatory comments. If another capture zone light source is captured, either of the light sources 24 or 26, the player may be less successful, but successful nevertheless and the comments may be less congratulatory. For example, if the center light source 25 is captured the player may receive five points, a refresh of five lives and a chance at a bonus round, but if either the light source 24 or 26 is captured the player may receive only one point. However, if another light source, other than the three light sources just mentioned, is captured, the player is considered to have failed and the indicator structure may again activate but with negative comments, for example. If the player is successful he may hear accolades from the speaker, and/or a light show from the light sources as well as an audio announcement of his current score. Thereafter, the game apparatus may be programmed to move to a higher level that may present a more difficult light sequence. If the player has been unsuccessful he may hear a disparaging comment, he may lose one of the five lives given to all players at the start of a game. With the loss of all five lives the game ends. The type of games played on the game apparatus requires intense concentration, a major feature of the game apparatus and its games.

The controller may be programmed with two solo games and multi-player versions of the same two games. In operation, a player may start or wake the game apparatus by activating the compression switch. The player may manipulate the multifunctional button to one side to select a game and to the other side to adjust the volume of the speaker. Activating the compression switch may be used to confirm the game selection. Moving the button when the game is in sleep mode may wake the apparatus to start a new game. The button may also be used to program the number of players involved. A first game may have the light sequence moving from one end of the housing to the other without stopping, called a complete run. A second game may have light sequences that are less predictable, such as incomplete runs, pauses and reversals before reaching the end of the housing. The second game is designed to trick the player into pressing the compression switch at the wrong time.

Although the illumination sequences of the second game are less predictable, the movement of light is cyclical to enable players to learn and anticipate light movement so as to improve play. In each game there may be twenty levels of play. The level determines the velocity of illumination movement and the complexity of the light sequence. Players advance to a next level when a light capture occurs in the zone. The speaker may announce each new level. Each level may repeat until a capture is made or until there has been twenty repetitions of the sequence without action by a player. Each player may start a game with “five lives” or five changes to fail, and he may lose a life or chance when an attempted capture is made outside the capture zone. The lives or chances may determine the length of each game. When all of the lives or chances are gone before a cycle of twenty levels are completed the game is over and a score may be announced and/or displayed. A capture of the center light source may refresh all five lives or chances, while a capture of light in the capture zone, but not the center light source, may not provide a refresh of lives or chances. After an attempted capture, the number of lives or chances remaining for that player may be displayed by one or more of the first five light sources, starting at the left, and/or the speaker may announce the number of lives or chances remaining

The bonus round may start after a short introduction and take the form of a ten second sequence consisting of a rapid and very unpredictable series of complete runs. The runs may be at a variety of velocities and one run may start before the end of a preceding run. A player may try to capture the light as often as he likes. A capture when the center light source only is illuminated may earn the player five points. The player may try for more captures, however, the light sequence does not loop and at the end of ten seconds the bonus round ends. Lives and levels may not be part of the bonus round.

A channel of audio may correspond to a playing light sequence, compression switch activation, and a response based on the result of an attempted capture. A second channel of audio may play a background melody in coordination with a playing light sequence to create a tempo, with a different melody for each level. The tempo may aid in timing a capture, may be irrelevant to capture, or may even be an intentional distraction.

By way of example, the games that may be played on the game apparatus may be a game for one player having twenty levels, with each new level being more difficult than the preceding level. The first five levels of this first game may have a tempo of 100 beats per minute and light source illumination duration of 0.06 seconds for the first two levels and illumination duration of 0.055 seconds for the next three levels. (For ease of understanding the light sources are renumber in the following examples from 1 to 11 which track the light sources 20, 21, 22, 23, 24, 25, 26, 27, 28, 29, 30, respectively, originally identified in relation to FIGS. 1-3. The blue center light source is now “5” instead of “25”.) The light source illumination sequence at level one may be the following: 1, 2, 3, 4, 5, 6, 7, 8, 9, 10, 11, 10, 9, 8, 7, 6, 5, 4, 3, 2. Level two may have the following sequence: 1, 2, 3, 4, 5, 6, 7, 8, 9, 10, 11, 11, 11, 11, 11, low, low, low, low, low, 11, 11, 11, 11, 11, low, low, low, low, low, 11, 10, 9, 8, 7, 6, 5, 4, 3, 2. (The term “low” means that the light source is energized at only 50% of usual brightness.) Level three may feature two light sequences at the same time, with the first pattern being: 1, 2, 3, 4, 5, 6, 7, 8, 9, 10, 11, 10, 9, 8, 7, 6, 5, 4, 3, 2, and the second pattern being 11, 10, 9, 8, 7, off, 5, 4, 3, 2, 1, 2, 3, 4, 5off, 7, 8, 9, 10. Level four may have the following sequence: 1, 2, 3, 4, 5, 6, 7, 8, 9, 10, 1, 2, 3, 4, 5, 6, 7, 8, 9, 10. The fifth level may have the following sequence: 1, 2, 3, 4, 5, 6, 7, 8, 9, 10, 11, 11, 11, 11, 11, low, low, low, low, low, 11, 10, 9, 8, 7, 6, 5, 4, 3, 2, 1, 1, 1, 1, 1, low, low, low, low, low, 1, 2, 3, 4, 5, 6, 7, 8, 9, 10, 11, 10, 9, 8, 7, 6, 5, 4, 3, 2, 1, 1, 1, 1, 1, low, low, low, low, low, 1, 1, 1, 1, 1, low, low, low, low, low. It is noted that a successful capture moves the player to the next level and a capture of the center light source, the blue light, refreshes the player's lives back up to five.

The second five levels may be played with light source illumination duration of 0.045 seconds and a tempo of 120 beats per minute. The pattern at level six may be as follows: 1, 2, 3, 4, 5, 6, 7, 8, 9, 10, 11, 10, 9, 8, 7, 6, 5, 4, 3, 2. Level seven may have the following sequence: 1, 2, 3, 4, 5, 6, 7, 8, 9, 10, 11, 11, 11, 11, 11, low, low, low, low, low, 11, 11, 11, 11, 11, low, low, low, low, low, 11, 10, 9, 8, 7, 6, 5, 4, 3, 2. Level eight may sequence two light patterns at the same time, with the first pattern being: 11, 10, 9, 8, 7, 6, 5, 4, 3, 2, 1, 2, 3, 4, 5, 6, 7, 8, 9, 10, 11, 11, 11, 11, 11, low, low, low, low, low, and the second pattern being 1, 2, 3, 4, 5, 6, 7, 8, 9, 10, 11 10, 9, 8, 7, 6, 5, 4, 3, 2, 1, 1, 1, 1, 1, low, low, low, low, low. The ninth level may have the following sequence: 11, 10, 9, 8, 7, 6, 5, 4, 3, 2, 11, 10, 9, 8, 7, 6, 5, 4, 3, 2. Level ten may have the following sequence: 1, 2, 3, 4, 5, 6, 7, 8, 9, 10, 11, 11, 11, 11, 11, low, low, low, low, low, 11, 10, 9, 8, 7, 6, 5, 4, 3, 2, 1, 1, 1, 1, 1, low, low, low, low, low, 1, 1, 1, 1, 1, low, low, low, low, low, 1, 1, 1, 1, 1, low, low, low, low, low, 1, 2, 3, 4, 5, 6, 7, 8, 9, 10, 11, 10, 9, 8, 7, 6, 5, 4, 3, 2.

The third five levels, levels eleven to fifteen, may be played with light source excitation duration of 0.04 seconds and a tempo of 150 beats per minute. The pattern at level eleven may be as follows: 1, 2, 3, 4, 5, 6, 7, 8, 9, 10, 11, 10, 9, 8, 7, 6, 5, 4, 3, 2. Level twelve may have the following sequence: 1, 2, 3, 4, 5, 6, 7, 8, 9, 10, 11, 11, 11, 11, 11, low, low, low, low, low, 11, 11, 11, 11, 11, low, low, low, low, low, 11, 10, 9, 8, 7, 6, 5, 4, 3, 2. The thirteenth level may sequence two light patterns at the same time, with the first pattern being: 11, 10, 9, 8, 7, 6, 5, 4, 3, 2, 1, 2, 3, 4, 5, 6, 7, 8, 9, 10, 11, 11, 11, 11, 11, low, low, low, low, low, 11, 10, 9, 8, 7, 6, 5, 4, 3, 2, 1, 2, 3, 4, 5, 6, 7, 8, 9, 10, 11, 10, 9, 8, 7, 6, 5, 4, 3, 2, 11, 10, 9, 8, 7, 6, 5, 4, 3, 2, 1, 1, 1, 1, 1, low, low, low, low, low, and the second pattern being: 1, 2, 3, 4, 5, 6, 7, 8, 9, 10, 11, 10, 9, 8, 7, 6, 5, 4, 3, 2, 1, 1, 1, 1, 1, low, low, low, low, low, 1, 2, 3, 4, 5, 6, 7, 8, 9, 10, 11, 10, 9, 8, 7, 6, 5, 4, 3, 2, 1, 2, 3, 4, 5, 6, 7, 8, 9, 10, 1, 2, 3, 4, 5, 6, 7, 8, 9, 10, 11, 11, 11, 11, 11, low, low, low, low, low. Level fourteen may have the following pattern: 1, 2, 3, 4, 5, 6, 7, 8, 9, 10, 1, 2, 3, 4, 5, 6, 7, 8, 9, 10, 11, 11, 11, 11, 11, low, low, low, low, low, 11, 11, 11, 11, 11, low, low, low, low, low, 11, 10, 9, 8, 7, 6, 5, 4, 3, 2, 11, 10, 9, 8, 7, 6, 5, 4, 3, 2, 1, 1, 1, 1, 1, low, low, low, low, low. The sequence for level fifteen may be the following: 1, 2, 3, 4, 5, 6, 7, 8, 9, 10, 11, 11, 11, 11, 11, low, low, low, low, low, 11, 10, 9, 8, 7, 6, 5, 4, 3, 2, 1, 1, 1, 1, 1, low, low, low, low, low, 1, 2, 3, 4, 5, 6, 7, 8, 9, 10, 11, 10, 9, 8, 7, 6, 5, 4, 3, 2.

The fourth and last five levels may be played with a light source illumination duration of 0.035 seconds for levels sixteen and seventeen, a duration of 0.03 seconds for levels eighteen and nineteen, and a duration of 0.02 seconds for level twenty, and a tempo of 170 beats per minute for all five levels. The sequence at level sixteen may be as follows: 1, 2, 3, 4, 5, 6, 7, 8, 9, 10, 11, 10, 9, 8, 7, 6, 5, 4, 3, 2. Level seventeen may have the following sequence: 1, 2, 3, 4, 5, 6, 7, 8, 9, 10, 11, 11, 11, 11, 11, low, low, low, low, low, 11, 10, 9, 8, 7, 6, 5, 4, 3, 2. Level eighteen may sequence two light patterns at the same time, with the first pattern being: 11, 10, 9, 8, 7, 6, 5, 4, 3, 2, 1, 2, 3, 4, 5, 6, 7, 8, 9, 10, 11, 11, 11, 11, 11, low, low, low, low, low, 11, 10, 9, 8, 7, 6, 5, 4, 3, 2, 1, 2, 3, 4, 5, 6, 7, 8, 9, 10, 11, 10, 9, 8, 7, 6, 5, 4, 3, 2, 11, 11, 11, 11, 11, low, low, low, low, low, and the second pattern being: 1, 2, 3, 4, 5, 6, 7, 8, 9, 10, 11, 10, 9, 8, 7, 6, 5, 4, 3, 2, 1, 1, 1, 1, 1, low, low, low, low, low, 1, 2, 3, 4, 5, 6, 7, 8, 9, 10, 11, 10, 9, 8, 7, 6, 5, 4, 3, 2, 1, 2, 3, 4, 5, 6, 7, 8, 9, 10, 1, 1, 1, 1, 1, low, low, low, low, low. Level nineteen may have the following pattern: 1, 2, 3, 4, 5, 6, 7, 8, 9, 10, 1, 2, 3, 4, 5, 6, 7, 8, 9, 10, 11, 11, 11, 11, 11, low, low, low, low, low, 11, 11, 11, 11, 11, low, low, low, low, low, 11, 11, 11, 11, 11, low, low, low, low, low 11, 10, 9, 8, 7, 6, 5, 4, 3, 2, 11, 10, 9, 8, 7, 6, 5, 4, 3, 2. The sequence for level twenty may be the following: 1, 2, 3, 4, 5, 6, 7, 8, 9, 10, 11, 11, 11, 11, 11, low, low, low, low, low, 11, 10, 9, 8, 7, 6, 5, 4, 3, 2, 1, 1, 1, 1, 1, low, low, low, low, low, 1, 1, 1, 1, 1, low, low, low, low, low, 1, 2, 3, 4, 5, 6, 7, 8, 9, 10, 11, 10, 9, 8, 7, 6, 5, 4, 3, 2, 1, 2, 3, 4, 5, 6, 7, 8, 9, 10, 11, 11, 11, 11, 11, low, low, low, low, low, 11, 10, 9, 8, 7, 7, 6, 5, 4, 3, 2, 1, 1, 1, 1, 1, low, low, low, low, low.

The first five levels of a second more difficult game may be played with a light source illumination duration of 0.06 seconds for the first two levels, a duration of 0.055 for the next two levels, and a duration of 0.05 for the fifth level, and a tempo of 100 beats per minute for all five levels. The first level may have the following sequence: 1, 2, 3, 4, 4, low, low, low, low, low, 4, 4, 4, 4, 4, low, low, low, low, low, 5, 6, 7, 8, 9, 10, 11, low, low, low, 11, 11, 11, 11, 11, low, low, low, low, low, 11, 10, 9, 8, 7, 6, 5, 4, 3, 2, 1, 2, 3, 4, 5, 6, 7, 8, 9, 10, 11, 10, 9, 8, 7, 6, 5, 4, 3, 2, 1, 1, 1, 1, 1, low, low, low, low, low. The second level may have the following sequence: 1, 2, 3, 4, 5, 6, 7, 8, 9, 10, 11, 11, 11, 11, 11, low, low, low, low, low, 11, 10, 9, 8, 7, 6, 7, 8, 9, 10, 11, 11, 11, 11, 11, low, low, low, low, low, 11, 10, 9, 8, 7, 6, 5, 4, 3, 2, 1, 1, 1, 1, 1, low, low, low, low, low, 1, 2, 3, 4, 5, 6, 5, 4, 3, 2, 1, 1, 1, 1, 1, low, low, low, low, low. The pattern for the third level may be as follows: 1, 2, 3, 4, 4, low, low, low, low, low, 4, 4, 4, 4, 4, low, low, low, low, low, 4, 4, 4, 5, 6, 7, 8, 9, 10, 11, 11, 10, 9, 8, 7, 6, 5, 4, 3, 2. The fourth level may have the following pattern: 1, 2, 3, 4, 4, 4, 4, 4, 3, 2, 1, 2, 3, 4, 5, 6, 7, 8, 9, 10, 11, 10, 9, 8, 8, 8, 8, 8, 9, 10, 11, 10, 9, 8, 7, 6, 5, 4, 3, 2. The fifth level may have the following pattern: 1, 2, 3, 4, 5, 6, 7, 8, 9, 10, 11, 10, 9, 8, 8, 8, 8, 8, 9, 10, 11, 10, 9, 8, 8, 8, 8, 8, 9, 10, 11, 10, 9, 8, 7, 6, 5, 4, 3, 2.

The second five levels of the more difficult game may be played with light source excitation duration of 0.045 seconds and a tempo of 120 beats per minute. The sixth level may have the following sequence: 1, 2, 3, 4, 4, low, low, low, low, low, 4, 4, 4, 4, 4, low, low, low, low, low, 5, 6, 7, 8, 9, 10, 11, low, low, low, 11, 11, 11, 11, 11, low, low, low, low, low, 11, 10, 9, 8, 7, 6, 5, 4, 3, 2, 1, 2, 3, 4, 5, 6, 7, 8, 9, 10, 11, 10, 9, 8, 7, 6, 5, 4, 3, 2, 1, 1, 1, 1, 1, low, low, low, low, low. The seventh level may have the following pattern: 1, 2, 3, 4, 5, 6, 7, 8, 9, 10, 11, 11, 11, 11, 11, low, low, low, low, low, 11, 10, 9, 8, 7, 6, 7, 8, 9, 10, 11, 11, 11, 11, 11, low, low, low, low, low, 11, 10, 9, 8, 7, 6, 5, 4, 3, 2, 1, 1, 1, 1, 1, low, low, low, low, low, 1, 2, 3, 4, 5, 6, 5, 4, 3, 2, 1, 1, 1, 1, 1, low, low, low, low, low. The eighth level may have the following pattern: 1, 2, 3, 4, 4, low, low, low, low, low, 4, 4, 4, 4, 4, low, low, low, low, low, 4, 4, 4, 4, 4, low, low, low, low, low, 4, 5, 6, 7, 4, 8, 9, 10, 11, 11, 1, 2, 3, 4, low, low, low, low, low, low, 4, 5, 6, 7, 4, 8, 9, 10, 11, 11. The sequence for the ninth level may be the following: 1, 2, 3, 4, 4, 4, 4, 4, 3, 2, 1, 2, 3, 4, 5, 6, 7, 8, 9, 10, 11, 10, 9, 8, 8, 8, 8, 8, 9, 10, 11, 10, 9, 8, 7, 6, 5, 4, 3, 2. The tenth level may have the following sequence: 1, 2, 3, 4, 5, 6, 7, 8, 9, 10, 11, 10, 9, 8, 8, 8, 8, 8, 9, 10, 11, 10, 9, 8, 8, 8, 8, 8, 9, 10, 11, 10, 9, 8, 7, 6, 5, 4, 3, 2.

The third five levels of the more difficult game may be played with momentary excitation duration of 0.04 seconds and a tempo of 150 beats per minute. The eleventh level may have the following pattern: 1, 2, 3, 4, 4, low, low, low, low, low, 4, 4, 4, 4, 4, low, low, low, low, low, 5, 6, 7, 8, 9, 10, 11, low, low, low, 11, 11, 11, 11, 11, low, low, low, low, low, 11, 10, 9, 8, 7, 6, 5, 4, 3, 2, 1, 2, 3, 4, 5, 6, 7, 8, 9, 10, 11, 10, 9, 8, 7, 6, 5, 4, 3, 2, 1, 1, 1, 1, 1, low, low, low, low, low. The twelfth level may have the following sequence: 1, 2, 3, 4, 5, 6, 7, 8, 9, 10, 11, 11, 11, 11, 11, low, low, low, low, low, 11, 10, 9, 8, 7, 6, 7, 8, 9, 10, 11, 11, 11, 11, 11, low, low, low, low, low, 11, 10, 9, 8, 7, 6, 5, 4, 3, 2, 1, 1, 1, 1, 1, low, low, low, low, low, 1, 2, 3, 4, 5, 6, 5, 4, 3, 2, 1, 1, 1, 1, 1, low, low, low, low, low. The pattern of the thirteenth level may be as follows: 1, 2, 3, 4, 4, low, low, low, low, low, 4, 4, 4, 4, 4, low, low, low, low, low, 4, 4, 4, 4, 4, low, low, low, low, low, 4, 5, 6, 7, 4, 8, 9, 10, 11, 11, 1, 2, 3, 4, low, low, low, low, low, low, 4, 5, 6, 7, 4, 8, 9, 10, 11, 11. The fourteenth level may have the following pattern: 1, 2, 3, 4, 4, 4, 4, 4, 3, 2, 1, 2, 3, 4, 5, 6, 7, 8, 9,10, 11, 10, 9, 8, 8, 8, 8, 8, 9, 10, 11, 10, 9, 8, 7, 6, 5, 4, 3, 2. The fifteenth level may have the following pattern: 1, 2, 3, 4, 5, 6, 7, 8, 9, 10, 11, 10, 9, 8, 8, 8, 8, 8, 9, 10, 11, 10, 9, 8, 8, 8, 8, 8, 9, 10, 11, 10, 9, 8, 7, 6, 5, 4, 3, 2.

The last five levels of the more difficult game may be played with an illumination duration of 0.035 seconds for levels sixteen and seventeen, a duration of 0.03 for levels eighteen and nineteen, and a duration of 0.02 for level twenty, and a tempo of 100 beats per minute for all five levels. The sixteenth level may have the following pattern: 1, 2, 3, 4, 4, low, low, low, low, low, 4, 4, 4, 4, 4, low, low, low, low, low, 5, 6, 7, 8, 9, 10, 11, low, low, low, 11, 11, 11, 11, 11, low, low, low, low, low, 11, 10, 9, 8, 7, 6, 5, 4, 3, 2, 1, 2, 3, 4, 5, 6, 7, 8, 9, 10, 11, 10, 9, 8, 7, 6, 5, 4, 3, 2, 1, 1, 1, 1, 1, low, low, low, low, low. The seventeenth level may have the following sequence: 1, 2, 3, 4, 5, 6, 7, 8, 9, 10, 11, 11, 11, 11, 11, low, low, low, low, low, 11, 10, 9, 8, 7, 6, 7, 8, 9, 10, 11, 11, 11, 11, 11, low, low, low, low, low, 11, 10, 9, 8, 7, 6, 5, 4, 3, 2, 1, 1, 1, 1, 1, low, low, low, low, low, 1, 2, 3, 4, 5, 6, 5, 4, 3, 2, 1, 1, 1, 1, 1, low, low, low, low, low. The sequence for the eighteenth level may be the following: 1, 2, 3, 4, 4, low, low, low, low, low, 4, 4, 4, 4, 4, low, low, low, low, low, 4, 4, 4, 4, 4, low, low, low, low, low, 4, 5, 6, 7, 4, 8, 9, 10, 11, 11, 1, 2, 3, 4, low, low, low, low, low, low, 4, 5, 6, 7, 4, 8, 9, 10, 11, 11. The nineteenth level may have the following pattern: 1, 2, 3, 4, 4, 4, 4, 4, 3, 2, 1, 2, 3, 4, 5, 6, 7, 8, 9, 10, 11, 10, 9, 8, 8, 8, 8, 8, 9, 10, 11, 10, 9, 8, 7, 6, 5, 4, 3, 2, 1, 1, 1, 1, 1, low, low, low, low, low. The twentieth level may have the following sequence: 1, 2, 3, 4, 5, 6, 7, 8, 9, 10, 11, 10, 9, 8, 8, 8, 8, 8, 9, 10, 11, 10, 9, 8, 8, 8, 8, 8, 9, 10, 11, 10, 9, 8, 7, 6, 5, 4, 3, 2, 1, 2, 3, 4, 4, 4, 4, 4, 3, 2, 1, 2, 3, 4, 5, 6, 7, 8, 9, 10, 11, 11, 11, 11, 11, low, low, low, low, low, 11, 10, 9, 8, 7, 6, 5, 4, 3, 2, 1, 2, 3, 4, 4, 4, 4, 4, 4, 4, 4, 4, 4, 4, 4, 4, 4, 4, 4, 4, 4, 4, 4, 4, 4, 4, 4, 4, 3, 2.

In the alternative, the various sequences or patterns may be altered from those disclosed by mixing those provided and/or creating new patterns or sequence segments. Also, point scores, the number of lives used, light source illumination durations and tempos may all be changed as desired. An objective of the invention is to create and maintain a high level of concentration and intensity to excite players of the game apparatus.

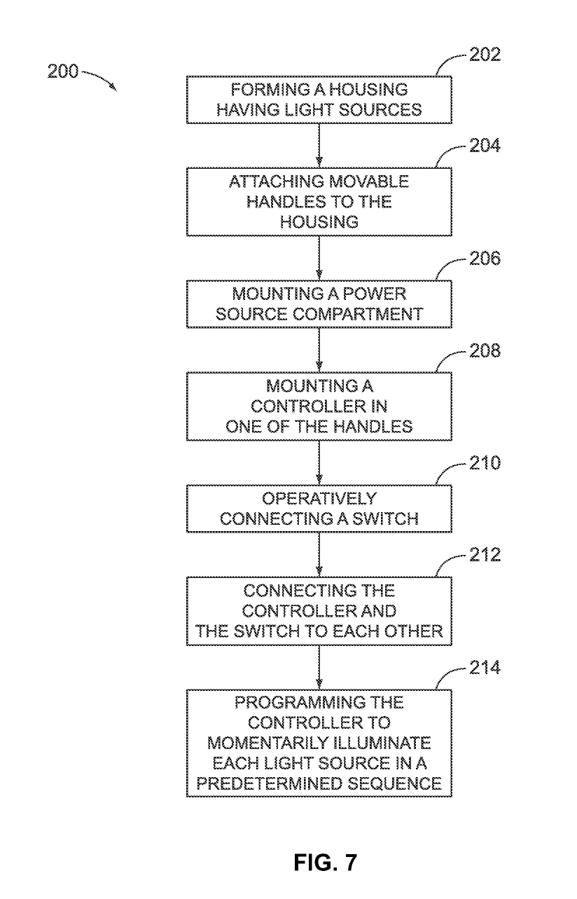

The present invention also includes a method for making a capture-the-light game apparatus, the steps of the method 200, FIG. 7, including forming a housing 202 with a longitudinal axis having a plurality of light sources in an extended arrangement, attaching a handle 204 at each end portion of the housing, the handles being mounted to enable movement parallel to the longitudinal axis of the housing, mounting a compartment 206 for a power source in one of the handles, mounting a controller 208 in one of the handles, operatively connecting a switch 210 to be activated by one of the handles, connecting the controller and the switch 212 to each other and to the power source, and programming the controller 214 to momentarily illuminate each or some of the plurality of light sources in predetermined sequences.

The game apparatus disclosed in detail above has great play value, is fun to play because of the concentration and intensity required, and is easy to operate in a safe manner, and yet the game apparatus has a robust, but simple structure, that may be produced at a reasonable cost.

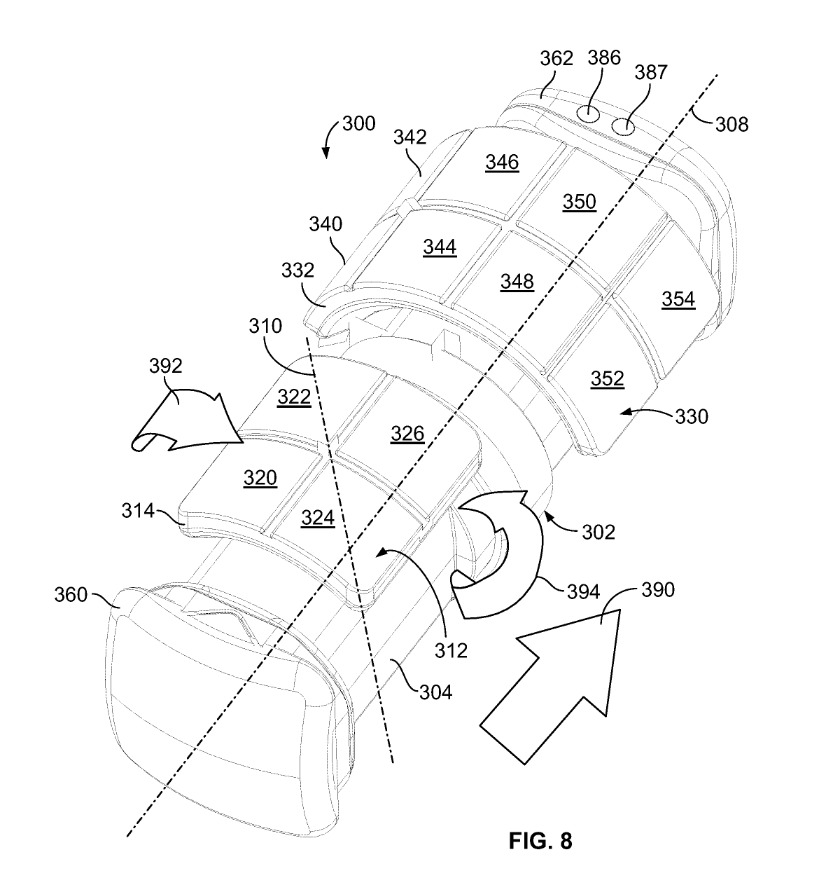

Referring now to FIGS. 8-14, there is shown another preferred embodiment of the present invention in the form of a hand-held light pattern game apparatus 300 in which a player may win or move toward winning by correctly transferring a lighted “puzzle piece,” whose shape is defined by a light pattern on a first array of lights, to a non illuminated “space” pattern on a second array of lights. The first array of lights is movable so that the puzzle piece shape is able to correctly align with the space provided. Games of varying difficulty may be arranged, and a number of game variations may be created.

The game apparatus 300 is similar to the game apparatus 10 and includes a generally cylindrical housing 302 divided into first and second portions 304, 306, where the housing portions 304, 306 are movable relative to each other. The housing has a central longitudinal reference axis 308, FIG. 1, and there is another reference axis 310 generally positioned in a perpendicular relationship to the longitudinal axis 308, as shown in FIG. 1. A first or puzzle piece array of lights 312 is mounted on a first support structure 314, the puzzle piece array of lights 312 including four light sources 320, 322, 324, 326. The first or left support structure 314 is mounted to the first or left housing portion 304, as viewed in FIGS. 8-11. A second or puzzle space array of lights 330 is mounted on a second or right support structure 332, the second array of lights 330 including eight light sources 340, 342, 344, 346, 348, 350, 352, 354. The second support structure 332 is mounted to the second or right housing portion 306. The extended ends of the housing include handles for gripping by a player, the handle 360 at the end of the left housing portion 304 and the handle 362 at the end of the right housing portion 306. In the alternative, more or less light sources may be included in one or both of the two arrays of lights.

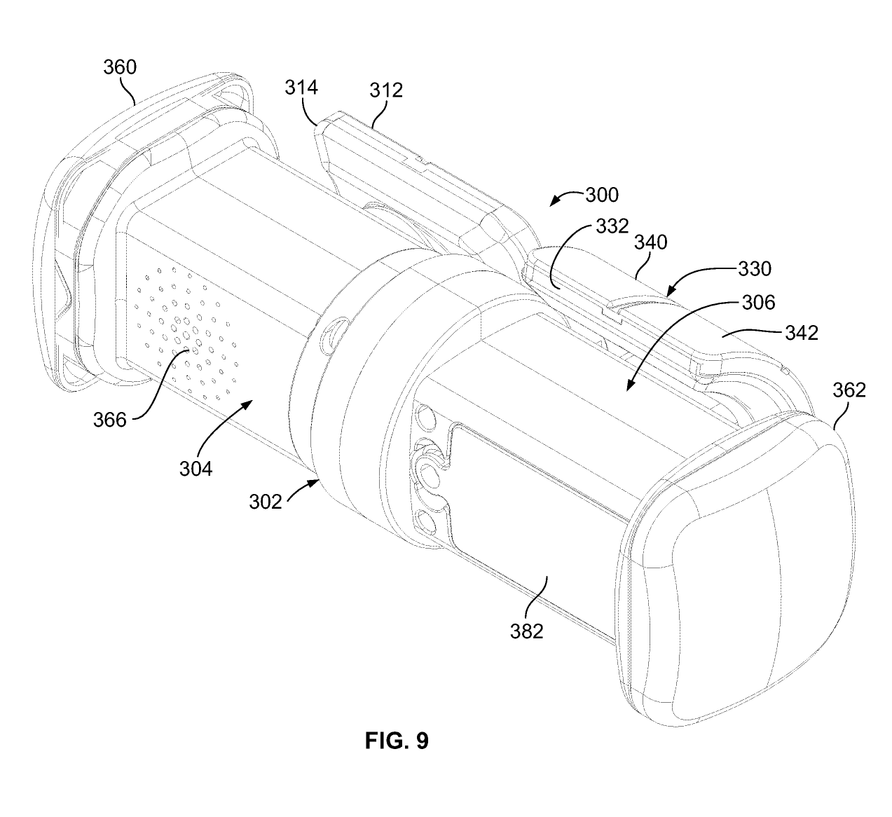

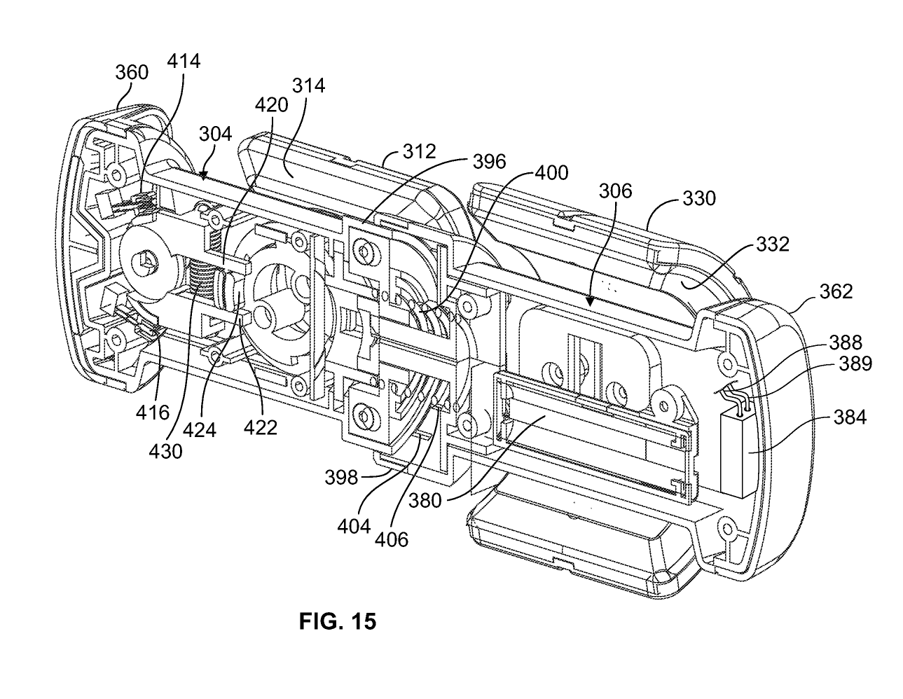

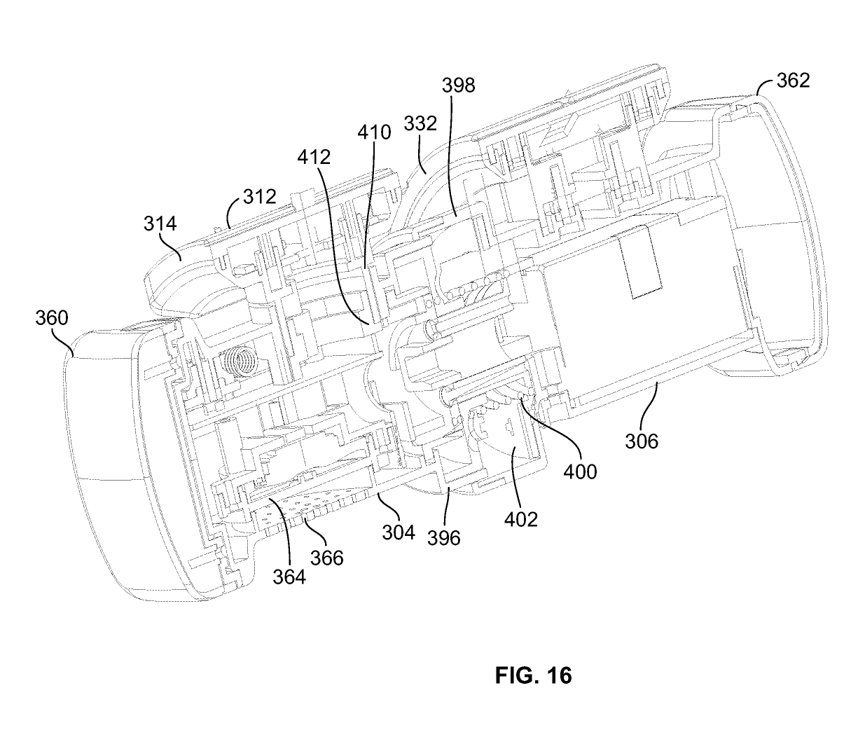

The light sources may be light emitting diodes (LEDs) covered by diffusers although different light sources may be used if convenient. The game apparatus may include a speaker 364, FIG. 16, behind a perforated panel 366, FIG. 9. Wires, such as the wires 370, 372, FIG. 13, in the left housing portion 304, and wires 374, 376 in the right housing portion 306, may connect the light sources of the puzzle piece array of lights 312 and the puzzle space array of lights 330 to batteries (not shown) mounted in a battery compartment 380, FIG. 15, behind a battery compartment cover 382, FIG. 9. The wires may also extend to a controller, symbolized by a box 384, FIG. 15, mounted in the handle 362. The controller 384 is also connected to the batteries, the speaker 364, a game selector button 386, FIG. 1, and a speaker volume control button 387 by wires, such as the wires 388, 389, FIG. 15.

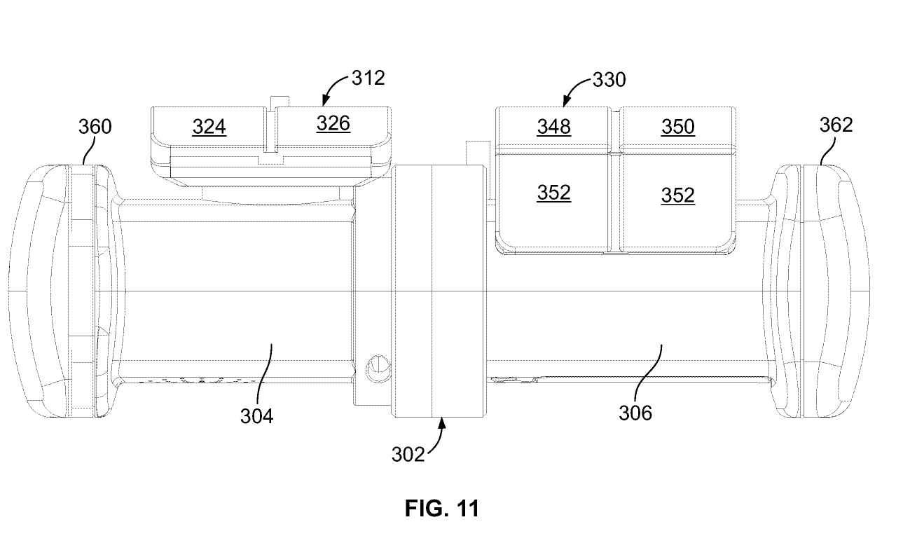

The left support structure 314, FIG. 8, with the first array of lights 312 is movable or translatable along with the first housing portion 304, in a direction parallel to the longitudinal axis 308, as symbolized by an arrow 390, and is rotatable about the longitudinal axis 308, along with the first housing portion 304, as symbolized by an arrow 392. Note that rotation may be clockwise or counterclockwise. The first array of lights 312 is also pivotal or twistable about the perpendicular axis 310, as symbolized by an arrow 394. The right support structure 332 with the second array of lights 330 is fixedly mounted to the right housing portion 306. Hence, the left housing portion 304 is both slidable and rotatable relative to the right housing portion 306 to allow movement of the left support structure 314 with the puzzle piece array of lights 312 in a direction parallel to the longitudinal axis 308 and in a direction around the longitudinal axis. The left housing portion 304 includes a cylindrical portion 396, FIG. 15, which telescopes into a cylindrical portion 398 of the right housing portion 306 to allow the sliding and rotational motions of the left housing portion relative to the right housing portion. A large coil spring 400 is mounted between the left and right housing portions to bias the housing portions apart, the left housing portion 304 to the left as shown in FIG. 11, and the right housing portion 306 to the right. A compression switch 402, FIG. 16, is connected to the left and right housing portions such that when a player, when holding the handles 360, 362 of the game apparatus, pushes the handles inward, a circuit is closed and a signal is sent to the controller 384.

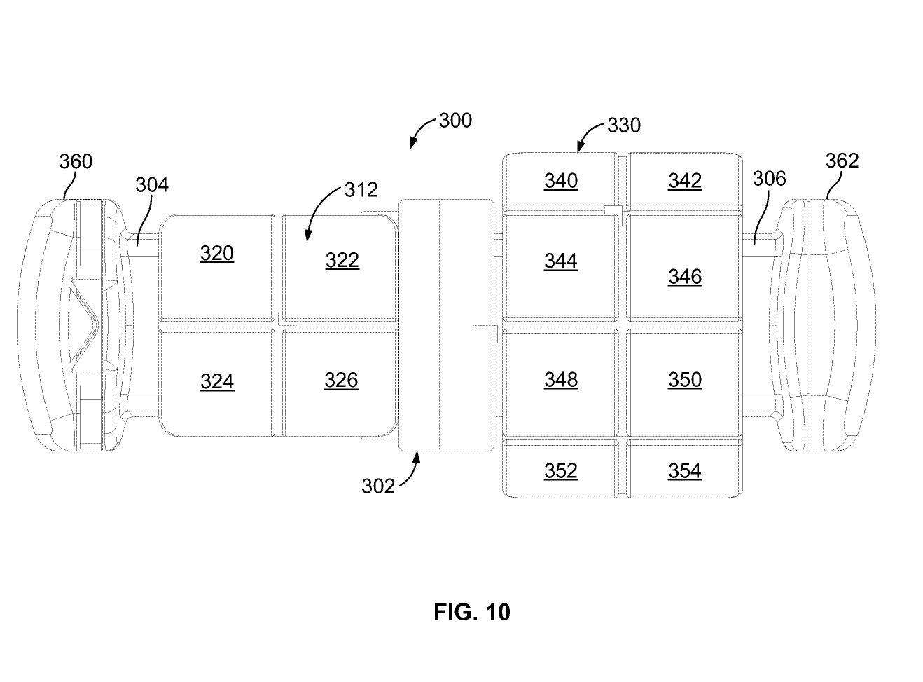

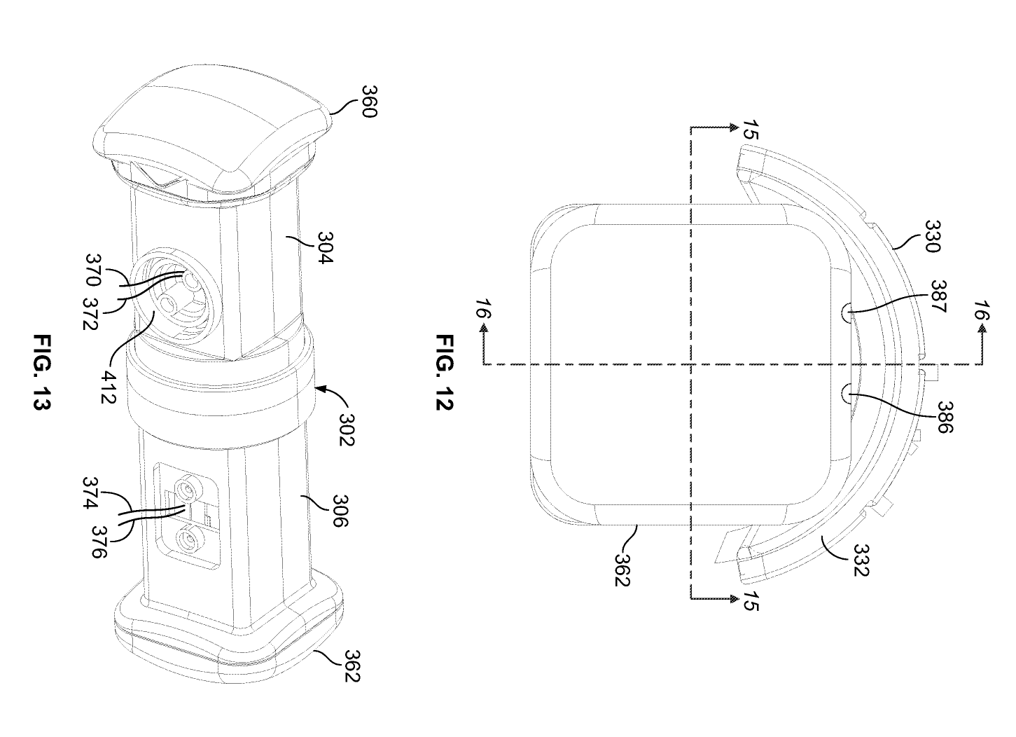

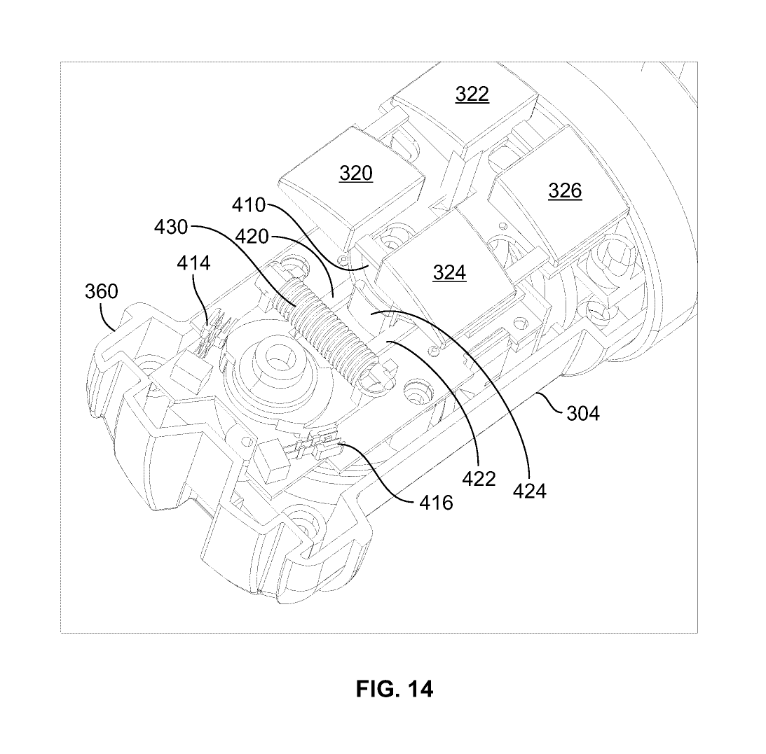

Electrical contacts and detents, such as the contact/detent 404, FIG. 15, and the contact/detent 406, are also placed around the cylindrical portion 398 of the right housing portion 306 such that the rotational position of the left housing portion 304 and, hence, the puzzle piece array of lights 312 is signaled to the controller 384 and rotational stops are discrete. Five detents may be used. The left support structure 314 to which is mounted the puzzle piece array of lights 312, is mounted to rotate relative to the left hand housing portion 306. The left support structure 314 includes a cylindrical portion 410, FIG. 16 and the left housing portion 304 includes a mating cylindrical portion 412, FIGS. 13 and 16. Two reed switches 414, 416, FIGS. 14 and 15, are mounted in the left housing portion 304 and are contacted by links 420, 422 that in turn are moved by a cam 424 included on the left support structure 314. When the left support structure 314 is twisted clockwise the reed switch 414 is activated. When the left support structure 314 is twisted counterclockwise the reed switch 416 is activated. A spring 430 is provided to return the left support structure 314 to a center or neutral position as shown in FIGS. 8 and 10.

During play, the controller 384 sends a signal that results in the puzzle piece array of lights illuminates a predetermined light pattern. The controller also sends a signal that the same pattern remains dark or not illuminated on the puzzle space array of lights 330. The player then observes the shape of the puzzle piece formed by the light pattern of the first array of lights as well as the dark or non-illuminated puzzle space on the puzzle space array of lights 330. Next, the player moves the left support structure 314 with the mounted array of lights 312 in rotation about the longitudinal axis 308 and/or about the perpendicular axis 310 to align the puzzle piece light pattern with the dark pattern of the puzzle space on the array of lights 330. It is noted that closing one of the reed switches 414, 416 by a relatively slight twist of the left support structure 314 signals the controller to translate the twist to a signal causing the puzzle piece light pattern to rotate a full 90°. Closing the same reed switch again rotates the puzzle piece light pattern another 90°. Rotating the left housing portion 304 from detent to detent, such as from detent 404 to detent 406 around the longitudinal axis 308 moves the puzzle piece array of lights 312 relative to the puzzle space array of lights 330 to one of several discrete locations. In the drawings, FIGS. 24-110, the array of lights 312 appears to move laterally across the sheets.

Once the player is satisfied with the position of the puzzle piece array of lights he/she moves the handles toward one another to squeeze the large coil spring 400 and close the compression switch 402. Closing the compression switch sends a signal to the controller that the puzzle piece light pattern on the first array of lights 312 is to be extinguished and that the same light pattern is to be illuminated on the puzzle space of the second array of lights 330, provided that the alignment of the arrays of lights is correctly made. When the player squeezes the coil spring it appears to him/ her and to other viewers that the first array of lights 312 touches the second array of lights 330 and that this touching causes the puzzle piece light pattern to be “transferred” from the first array of lights 312 to the second array of lights 330. It is noted that this light transfer appearance is similar to the appearance of light moving along the housing of the earlier described game apparatus 10. And like the game apparatus 10, where the player scores if the light stops at the predetermined correct position, in the game apparatus 300, if the puzzle piece light pattern of the first array of lights 312 matches or is correctly aligned with the puzzle space of the second array of lights 330 the player is rewarded. If the puzzle piece light pattern is not correctly aligned, the player fails and receives some detriment.

An indicator structure for the game apparatus 300 is mounted to the housing 302 and is operatively connected to the controller 384 and the compression switch 402. This connection informs the game player whether the compression switch is closed correctly, that is, whether the transfer of the puzzle piece is correctly made to the puzzle space. The indicator structure may include the controller 384 which causes a signal to be sent to the speaker 364 to emit a sound or sounds, such as a tune and/or words, and/or the controller may cause a signal to one or both of the arrays of lights 304, 306 to flash brightly. Thus, the speaker and arrays of lights may also be of the indicator structure.

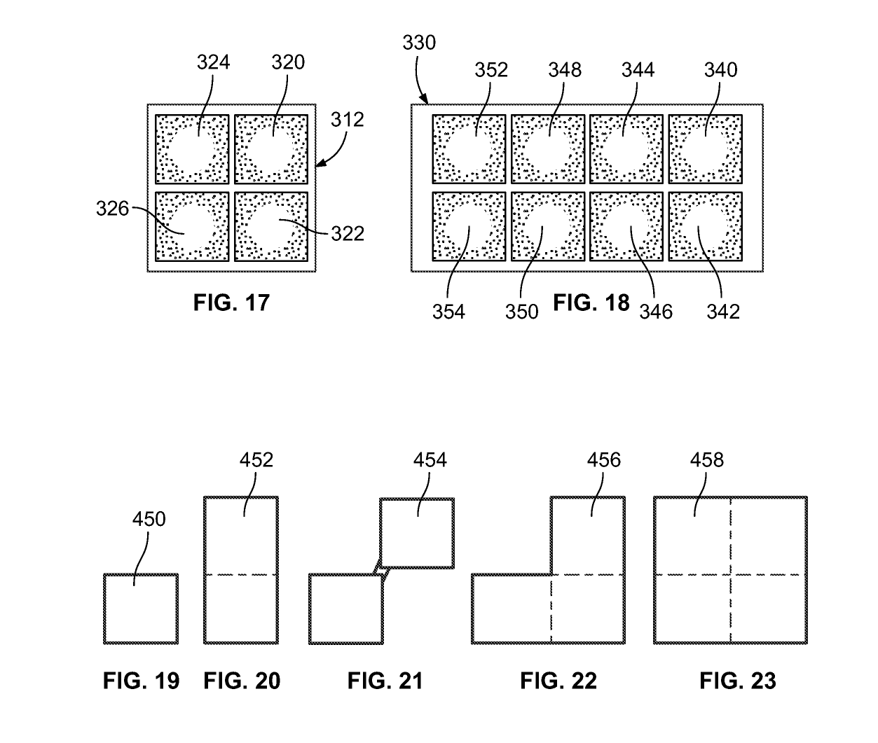

To explain how the game apparatus may actually be played, the puzzle piece array of lights 312 is shown in a planar layout in FIG. 17, for illustrative purposes, and has the four light sources 320, 322, 324, 326. The puzzle space array of lights 330 is also shown in a planar layout in FIG. 18, also for illustrative purposes, and has the eight light sources 340, 342, 344, 346, 348, 350, 352, 354. The controller causes illumination of the light sources of the puzzle piece array of lights 312 in various patterns as illustrated in FIGS. 19-23, and these patterns are the puzzle pieces that are to be handled by the player. A single light source appears as a small square 450, FIG. 19, two linearly aligned light sources appears as a rectangle 452, FIG. 20, two obliquely aligned light sources appear as a slanted dumbbell or bowtie 454, FIG. 21, three light sources appear as a backward or inverted “L” or angle 456, FIG. 22, and the four light sources of the puzzle piece array of lights appear as a large square 458, FIG. 23.

For clarity, dark outlines are drawn around each of the light patterns shown in FIGS. 19-23, to illustrate how each puzzle piece light pattern is to be considered by the player when playing a game. The light sources of the puzzle space array of lights 330 may be paired and remain dark in similar patterns such that the illuminated patterns of the puzzle piece array of lights may be “transferred” to the dark or non-illuminated patterns of the puzzle space array of lights in one or more moves or playing rounds, provided that the player achieves a correct alignment of the two arrays of lights. In one game, the objective is to eventually use several puzzle piece light patterns to illuminate all eight of the light sources of the puzzle space array of lights, thereby “filling in” all the puzzle pieces as in a traditional cardboard puzzle. In another game, the object is to transfer “bombs” from the puzzle piece array of lights to an illuminated puzzle space array of lights and after the transfer the light sources of the illuminate puzzle space array of lights turn dark, somewhat of a reversal of the first mentioned game.

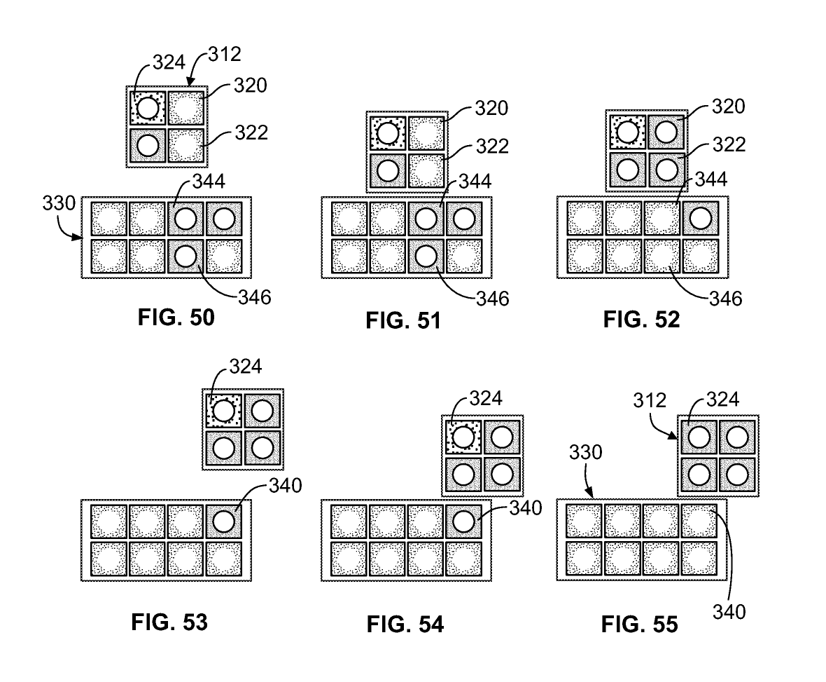

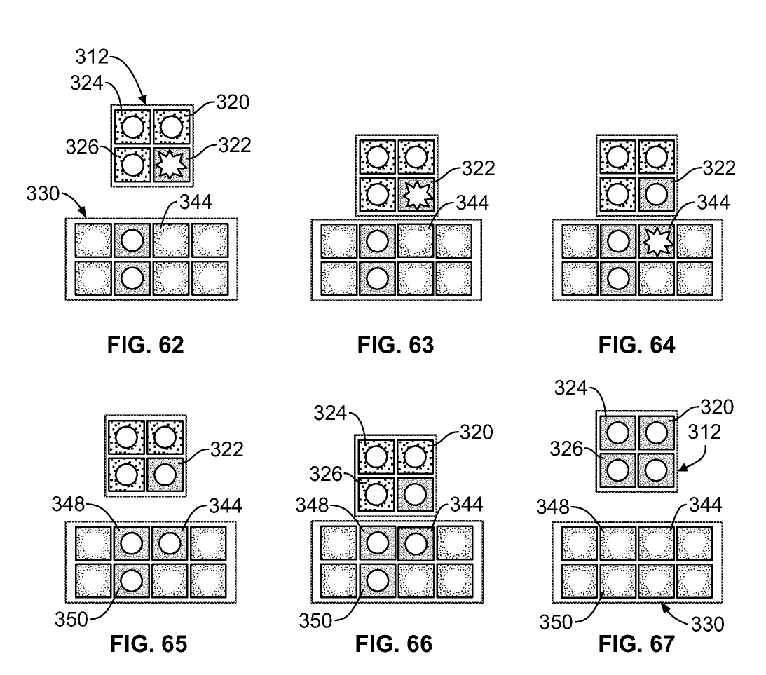

In the drawings, starting at FIG. 24, a light source is illuminated if the background around a white circle is moderately stippled, and the light source is dark or non-illuminated if the background around a white circle is densely or highly stippled. Starting at FIG. 50, a light stipple means that the light source is illuminated in a color, such as blue, which is different from the color, such as green, of the moderately stippled light source. Starting at FIG. 62, a multi-pointed star is used for a flashing bomb that, upon transfer, turns an illuminated light source dark.

As mentioned regarding the first game, the puzzle piece array of lights 312 mounted on the left support structure 314 may have to be rotated around the longitudinal axis and/or twisted around the perpendicular axis to correctly align a puzzle piece light pattern of the array of lights 312, the puzzle piece shape being represented by the illuminated shape of its light sources, with the puzzle space available on the array of lights 330, represented by a pattern of non-illuminated light sources. When a player is satisfied with the alignment of the two arrays of lights he/she moves the left housing portion 304 toward the right housing portion 306 to close the compression switch 402. Closing the compression switch signals the controller to extinguish the light pattern of the puzzle piece array of lights, if the alignment is correct, and illuminate the same light pattern on the puzzle space array of lights. The game is played as if the illuminated light sources of the puzzle piece array of lights 312 are a single physical puzzle piece that is aligned with an identical (or partially identical in some games) dark space formed by non-illuminated light sources on the puzzle space array of lights 330. The program of the controller may also require that the correct alignment occur within a predetermined time period or the player fails to make a score. A tune may be played through the speaker to help a player with rhythm or cause a distraction, and a voice may be used to announce scores, level of play, taut the player, or the like.

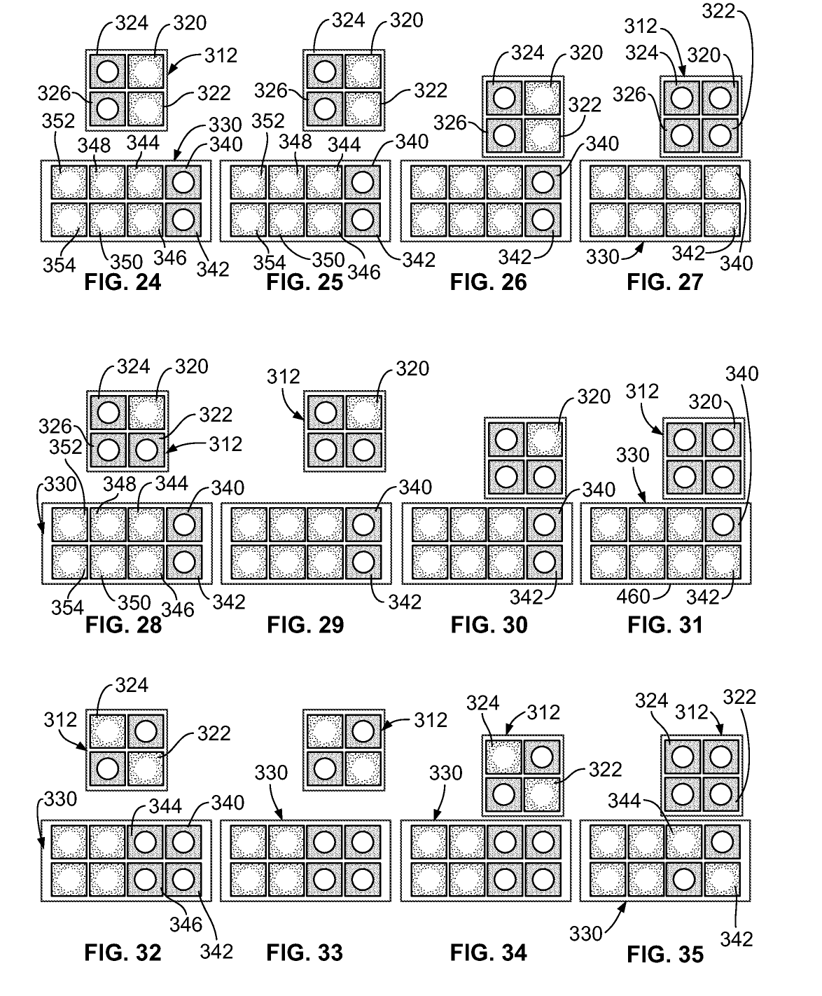

Referring now to FIGS. 24-27, examples are provided showing actual play of the puzzle game apparatus 300. Illustrated in FIG. 24, the puzzle piece array of lights 312 has a light pattern of two linearly aligned illuminated light sources 320, 322, like the rectangle pattern 452 shown in FIG. 20. The remaining two light sources 324, 326 are dark. The puzzle space array of lights 330 show six illuminated light sources 344, 346, 348, 350, 352 and a rectangular pattern of two linearly aligned dark or non-illuminated light sources 340, 342. For the player to align the puzzle piece array of lights 312 with the puzzle space array of lights 330, he/she rotates the left housing portion 304 about the axis 308 in a counterclockwise direction, see FIG. 8, such that the two linearly aligned illuminated light sources 320, 322 are aligned with the two linearly aligned dark light sources 340, 342, as shown in FIG. 25. Next, the player moves the first or left housing portion 304 toward the second or right housing portion 306, as shown in FIG. 26, to squeeze the compression switch 402. Because the alignment is correct, the puzzle piece is “transferred” from the array of lights 312 to the puzzle space on the array of lights 330, as shown in FIG. 27, where the light sources 320, 322 go dark and the light sources 340, 342 are illuminated. As mentioned above, the term “transfer” is used here to give the appearance of a physical movement of an illuminated puzzle piece from the first array of lights 312 to the second array of lights 330 even though the movement is accomplished electronically. The result of this example is that all of the light sources of the puzzle piece array of lights 312 are dark and all of the light sources of the puzzle space array of lights 330 are illuminated indicating that the puzzle is complete and that the player may move to the next round which may be more difficult.

Referring now to FIGS. 28-31, the puzzle piece is the single illuminated light source 320, FIG. 28, like the small square 450 shown in FIG. 19. The remaining light sources 322, 324, 326 are dark. On the puzzle space array of lights there are two non-illuminated light source spaces 340, 342. As shown in FIG. 29, the puzzle piece array of lights 312 is rotated counterclockwise about the longitudinal axis 308 so that the light source 320 is aligned with the light sources 340, 342. The player then moves the left housing portion 304 toward the right housing portion 306, FIG. 30, usually by squeezing the handles 360, 362, causing the puzzle piece to transfer from the puzzle piece array of lights “through” the dark light source 340 to the dark light source 342, the furthest available “open” puzzle space on the puzzle space array of lights 330, as shown in FIG. 31. It is noted that if the puzzle piece occupied the space of the light source 340, the space of the light source 342 becomes blocked and the puzzle can no longer be completed. A rule of play is that a puzzle shape may move across a dark space in either array of lights until the puzzle shape electronically collides with either an occupied space which is illuminated or the puzzle piece hits a border 460 of the puzzle space array of lights 330, as shown in FIG. 31. The player does not need to fill all puzzle spaces in one move, the puzzle piece just needs to fit into an available space in the puzzle space array of lights. As also shown in FIG. 31, the light sources of the puzzle space array of lights 330 are not all illuminated. In that situation, another puzzle piece will appear on the puzzle piece array of lights 312. The controller may be programmed such that the patterns that appear in the puzzle piece array of lights 312 will have a paired puzzle space in the puzzle space array of lights 330 until the player completes the puzzle, provided that the player does not make too many incorrect moves causing the game to terminate.

Referring to FIGS. 32-35, the puzzle piece is a bowtie pattern formed by the light sources 322, 324 and the available space pattern on the puzzle space array of lights 330 is a large square of four non-illuminated light sources 340, 342, 344, 346, as shown in FIG. 32. As before, the puzzle piece array of lights 312 is moved counterclockwise around the longitudinal axis 308 to align the puzzle piece with the four non-illuminated light sources as shown in FIG. 33. The arrays of lights are then brought together as shown in FIG. 34, to transfer the bowtie pattern to the dark light sources 342, 344 on the puzzle space array of lights 330 because they were available, as shown in FIG. 35.

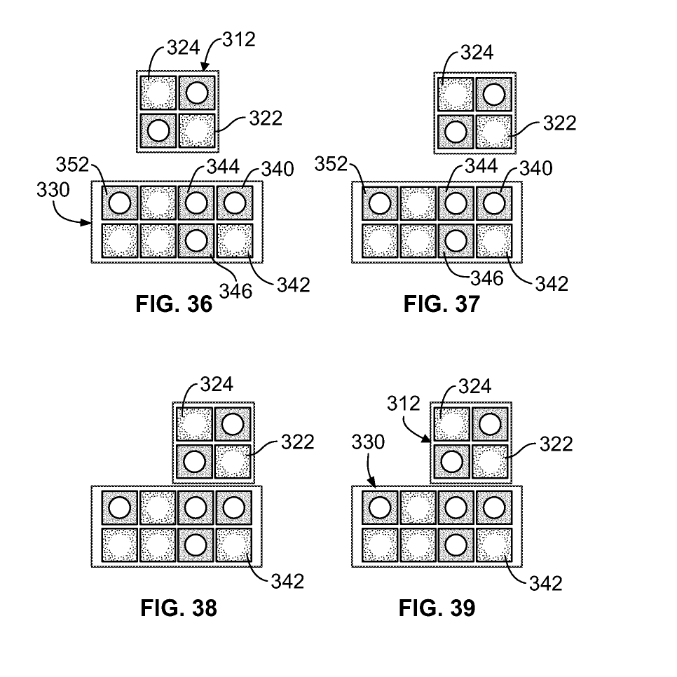

In contrast to the successful move of the bowtie puzzle piece shown in FIGS. 32-35, reference is now made to FIGS. 36-39, to illustrates an incorrect or failed transfer attempt. The controller again causes a bowtie puzzle piece to be formed by the illuminated light sources 322, 324, however, the puzzle space array of lights has four dark light sources 340, 344, 346, 352, in a spaced apart arrangement, as shown in FIG. 36. After an attempted alignment and transfer shown in FIGS. 37 and 38, there is an interference between the light source 322 and the light source 342, which is illuminated, and thus not an open puzzle space, so that a transfer of the bowtie puzzle piece does not take place as shown in FIG. 39. The attempted transfer results in a failure.

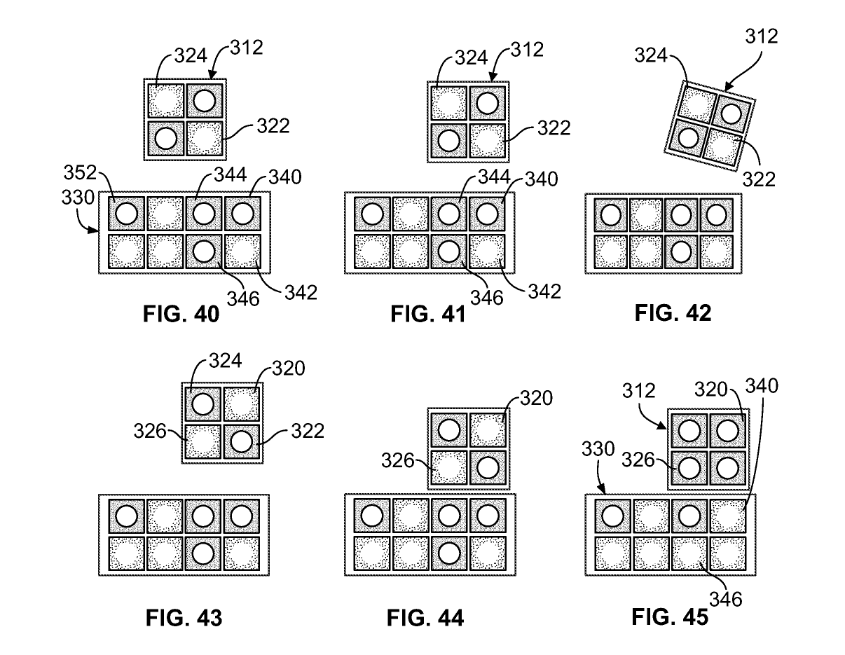

The problem highlighted in relation to the interference or obstacle shown in FIGS. 36-39, is solved by reference to FIGS. 40-45. The beginning position as well as the first move of the puzzle piece is illustrated in FIGS. 40 and 41, and are identical to the illustrations of FIGS. 36 and 37. The next correct move that the player should make is to twist the first structure so that one of the reed switches 414, 416 is closed. Closing a reed switch sends a signal to the controller that, in turn, will signal the puzzle piece array of lights 312 to appear to rotate 90° as shown in FIGS. 42 and 43. A rotation of 90° is simply accomplished by the light sources 322 and 324 going dark and the light sources 320 and 326 being illuminated. Referring to FIGS. 44 and 45, it can be seen that a successful transfer is made when the light sources 320, 326 go dark and the dark light sources 340, 346 are illuminated because the dark light sources 340, 346 match the bowtie shape of the puzzle piece and there are no obstacles.

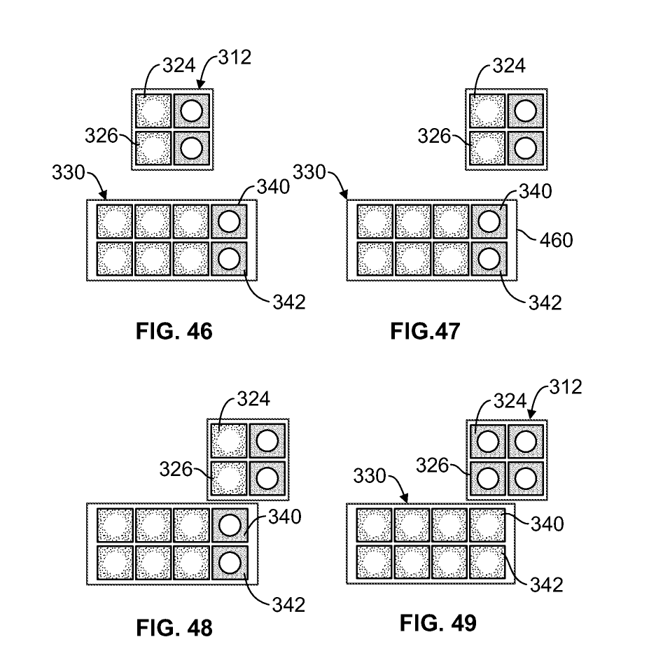

Still another game technique is illustrated in FIGS. 46-49, where the puzzle piece array of lights 312 may be moved from a starting position shown in FIG. 46, counterclockwise two detents to an “overhang” position shown in FIG. 47. An overhang position means that the puzzle piece array of lights is rotated to a detent position beyond the border 460 of the puzzle space array of lights 330 so as to align the illuminated rectangle formed by the light sources 324, 326 with the dark puzzle space light sources 340, 342. It is noted that the dark light sources of the first array of lights 312 extend beyond the border 460 of the array of lights 330. Bringing the arrays of lights together, as shown in FIG. 48, closes the compression switch 402, and causes a transfer of the puzzle piece. The result is that the light sources 324, 326 go dark and the light sources 340, 342 are illuminated, as shown in FIG. 49. It is noted that if either light source 320, 322 were illuminated no transfer would be possible because a puzzle piece or a part of a piece cannot move beyond the border of the puzzle space array of lights 330, although in a variation discussed below such a move is allowed.

A more difficult variation of the game apparatus is illustrated in FIGS. 50-55, where the puzzle piece array of lights 312 shows two puzzle piece light patterns at the same time. This arrangement may be accomplished by using two different colors, for example, a first puzzle piece light pattern, a rectangle, consisting of the light sources 320, 322 in green, and a second puzzle piece light pattern, a small square, consisting of the light source 324 in blue, as shown in FIG. 50. It is noted that for the drawings here, the color green is represented by a denser stipple than is the color blue, or, a moderate stipple for the color green as compared to a light stipple for the color blue. Using a game rule that the green pattern, here the rectangle, must be transferred first, attention is focused on proper alignment of the light sources 320, 322. To correctly transfer the rectangular puzzle piece, the green light sources 320, 322 are aligned with the dark puzzle spaces 344, 346, as shown in FIG. 50 and the arrays of lights are brought together as shown in FIG. 51. The light sources 320, 322 go dark and the light sources 344, 346 are illuminated, as shown in FIG. 52. Next, the player must move the puzzle piece array of lights to align the blue light source 324 with the dark light source 340 as shown in FIG. 53, such that when brought together, FIG. 54, a transfer results, FIG. 55, where the blue puzzle piece light source 324 goes dark and the green puzzle space light source 340 is illuminated, as shown in FIG. 55. The color change during transfer is of no consequence in this game variation.

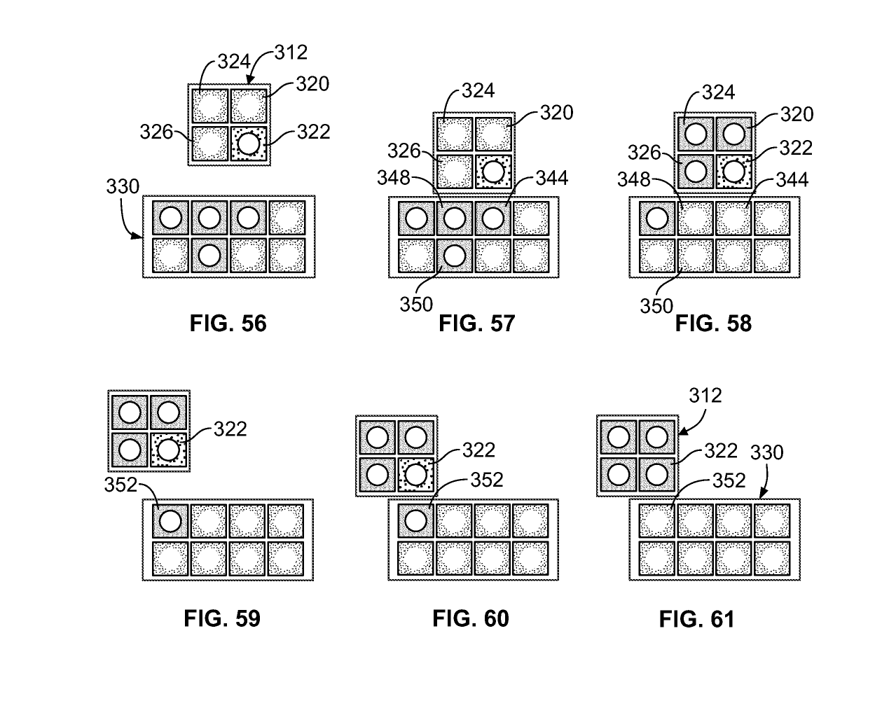

Another rule for playing with two puzzle pieces in the same round is illustrated in FIGS. 56-61. One puzzle piece is a green angle of three light sources 320, 324, 326 and the other puzzle piece is a blue small square of the light source 322, as shown in FIG. 56. Correct alignment is shown in FIG. 56, because another rule is that a green puzzle piece is able to pass through a blue puzzle piece, such that a transfer of the green angle is programmed to pass through the blue small square as shown in FIGS. 57 and 58, where the green light sources 320, 324, 326 go dark and the light sources 344, 348 and 350 are illuminated while the blue light source 322 remains illuminated. Thereafter, the player must align the blue puzzle piece light pattern with the dark light source 352, as shown in FIG. 59. Moving the arrays of lights together causes a transfer as shown in FIGS. 60 and 61, where the blue light source 322 goes dark and the green puzzle space light source 352 is illuminated.

Yet another variation of a game apparatus is shown in FIGS. 62-67, in which a flashing “bomb” puzzle piece in the form of a small square light source 322 is used to create a space in the puzzle space array of lights 330 to allow a transfer of a larger puzzle piece from the first array of lights to the second array of lights. In the example shown, the bomb light source 322 is aligned with the illuminated puzzle space light source 344 so that an extra space is created in the puzzle space array of lights 330 to help accommodate the angle puzzle piece formed by the light sources 320, 324, 326, as shown in FIGS. 62-64. By using the bomb, an angle shaped space is formed by the player extinguishing the illuminated light source 344. With the light source 344 now dark and added to the dark light sources 348, 350, as shown in FIG. 65, the angle puzzle space is created for the angle puzzle piece. Aligning the angle puzzle piece with the angle puzzle space allows a successful transfer to be made, as shown in FIGS. 66 and 67. As an alternative to the flashing bomb light source, a light source used for a bomb may have another color, such as red. The process of creating a space on the array of lights 330 with a red bomb remains the same as with a flashing bomb.

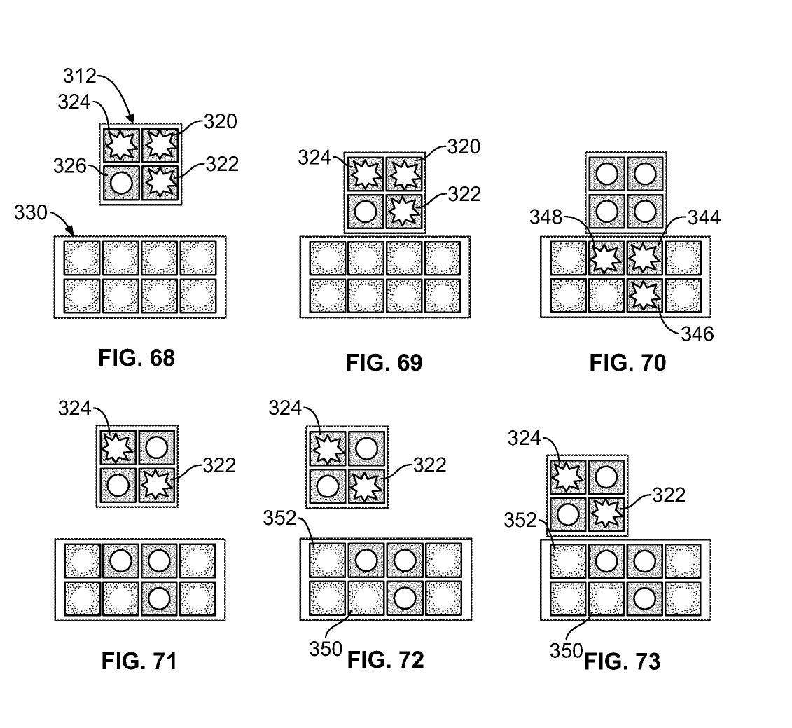

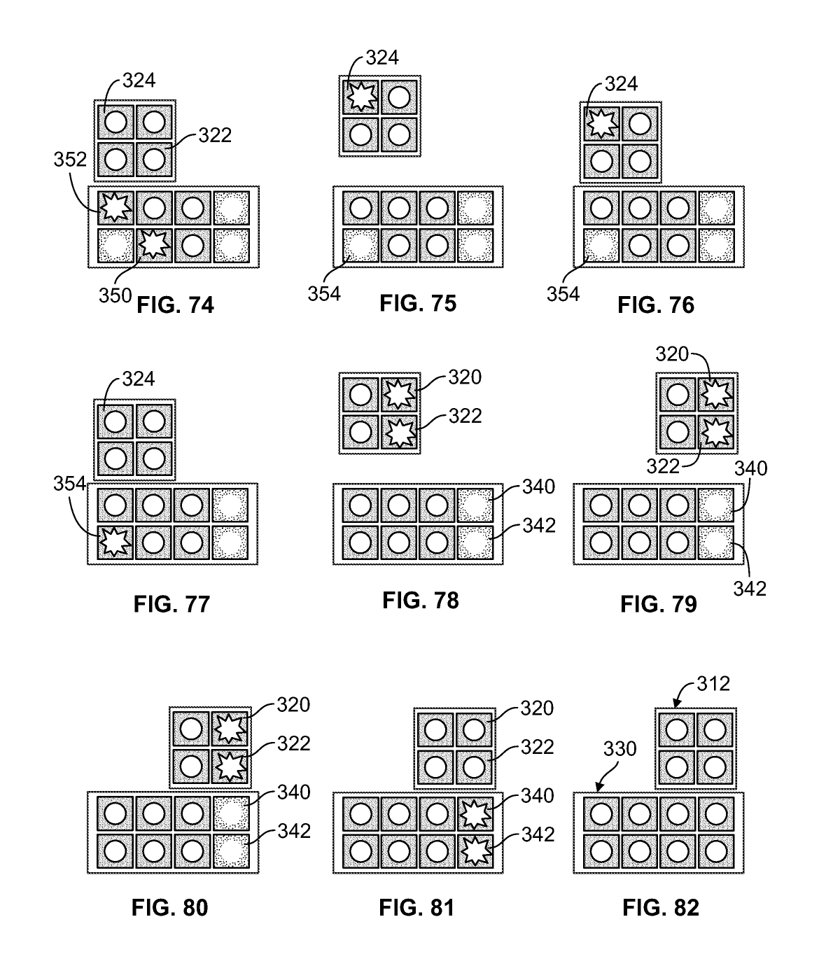

Still another variation is shown in FIGS. 68-82. Each of the puzzle piece light patterns consists of bombs and the object is to “blackout” all of the light sources in the puzzle space array of lights 330 which are all initially illuminated, as shown in FIG. 68. A pattern of bombs is place on the puzzle piece array of lights 312, such as the angle of light sources 320, 322, 324. Upon transfer, shown in FIGS. 69 and 70, the light sources 344, 346, 348 are extinguished. The next puzzle piece includes a bowtie bomb formed by the light sources 322, 324 shown in FIG. 71. As shown in FIGS. 72-74, after alignment and transfer, the light sources 350, 352 are extinguished. Referring to FIGS. 75-77, the next bomb is formed of the small square light source 324, and after alignment and transfer, the light source 354 is extinguished. The last bomb pattern is shown in FIG. 78, where the bomb puzzle piece is a rectangle formed by the light sources 320, 322. After alignment, shown in FIG. 79, and transfer, shown in FIGS. 80-82, the light sources 340, 342 go dark or blacked out, thereby completing the extinguishing of all of the light sources of the puzzle space array of lights 330.

It is noted that the controller is programmed to offer up only four light patterns, an angle, a bowtie, a small square, and a rectangle so that a good player is able to complete the blackout in a minimum amount of time. The blackout round may be played against a clock where the player keeps playing more than one round until a predetermined time period expires, and the same four light patterns may be presented in a random order. If a player fails to use just four moves, the controller is programmed to produce completely random shapes until blackout is achieved or the time period expires.

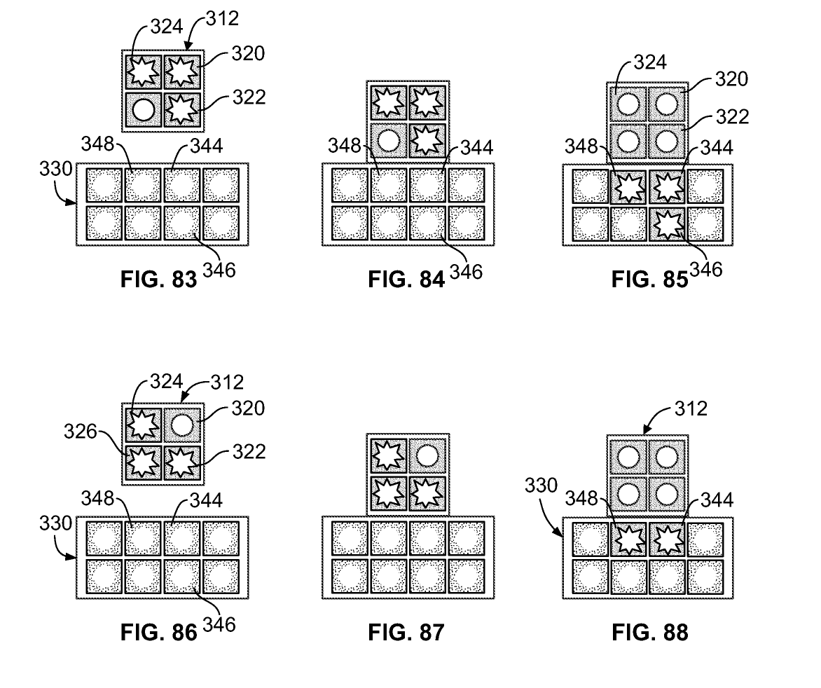

The blackout rounds just described above in detail may include certain rules that make each round different and more difficult. For example, if an angle bomb appears in the first array of lights 312, as shown in FIG. 83, with a “point,” the single light source 322, making first contact with the second array of lights 330, the entire angle passes through the illuminated light source 344 resulting in all three light sources 344, 346, 348 being extinguished, as shown in FIGS. 84 and 85. However, when the angle bomb is as shown in FIG. 86, with the light sources 322, 324, 326 flashing, and there are obstructions, then no piercing is allowed so that a transfer only extinguishes the light sources 344, 348, as shown in FIGS. 87 and 88. If light source 344 is already extinguished as shown in FIG. 89, than the angle bomb of light sources 322, 324, 326, upon transfer, extinguishes the three light sources 346, 348, 350 as shown in FIGS. 90 and 91.

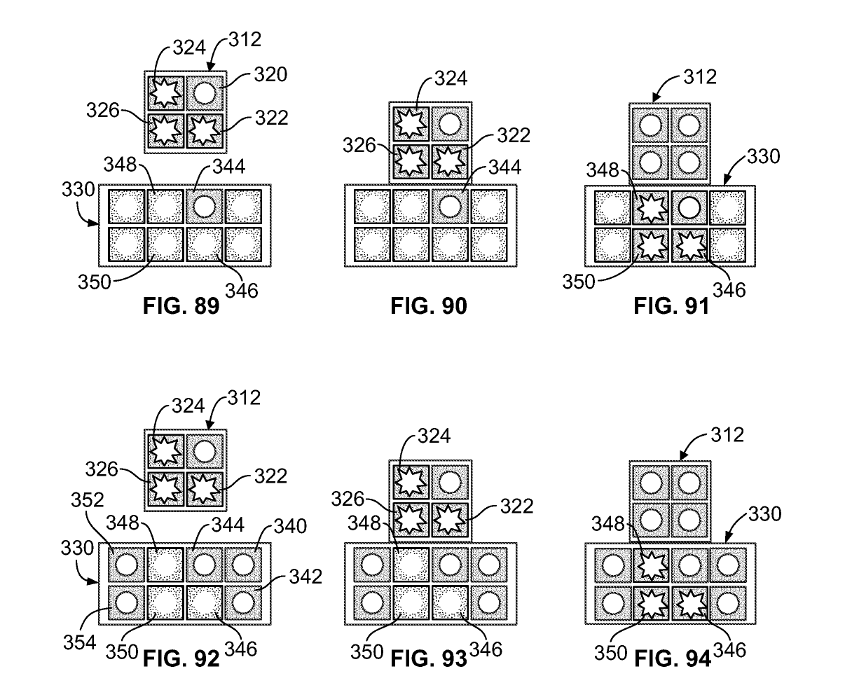

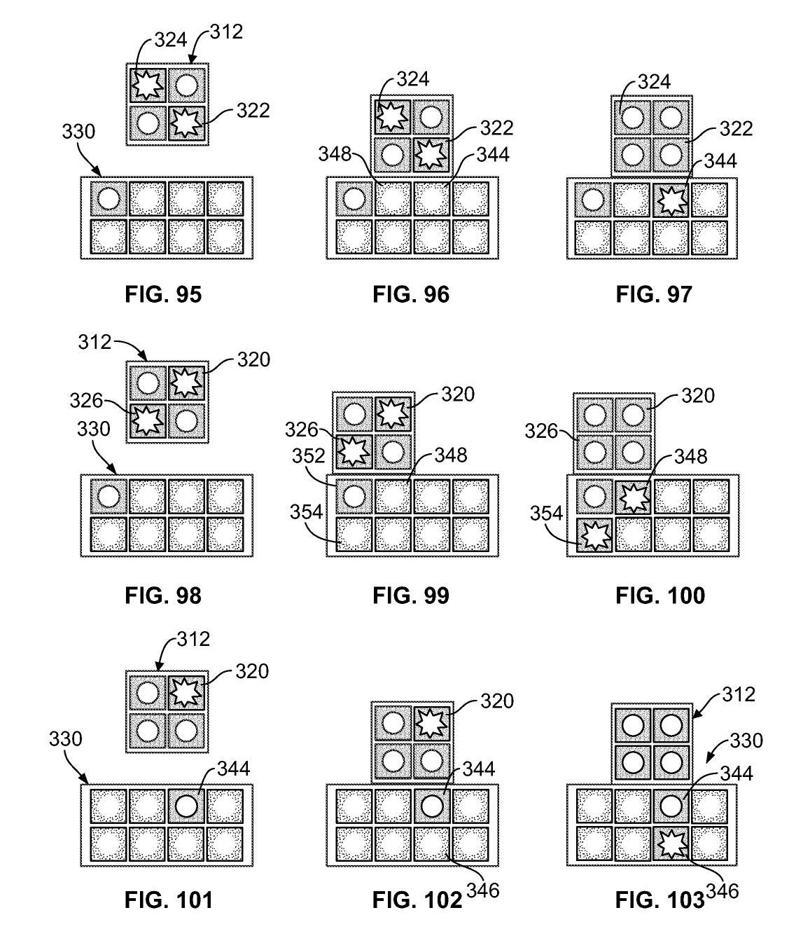

The same rule is observed with regard to the arrangement of light sources shown in FIGS. 92-94. With bombs indicated by the light sources 322, 324, 326 in the puzzle piece light array 312, and the light sources 340, 342, 344, 352, 354 being dark and the light sources 346, 348, 350 being illuminated, there is no obstruction to an angle bomb transfer shown in FIGS. 93 and 94. Referring to FIG. 95, when a bowtie bomb appears in the puzzle piece array of lights 312 and the puzzle space array of lights 330 are all illuminated, except for the light source 352 which is dark, where the alignment occurs as shown in FIG. 96, only the light source 344 goes dark as shown in FIG. 97, because the first contact by one bomb blows up both bombs, or viewed another way, there is an obstacle. But, when the bowtie bombs are rotated 90°, as shown in FIG. 98, and aligned differently, as shown in FIG. 99, the dark light source 352 is no longer an obstacle and the two light source 348, 354 go dark, as shown in FIG. 100.

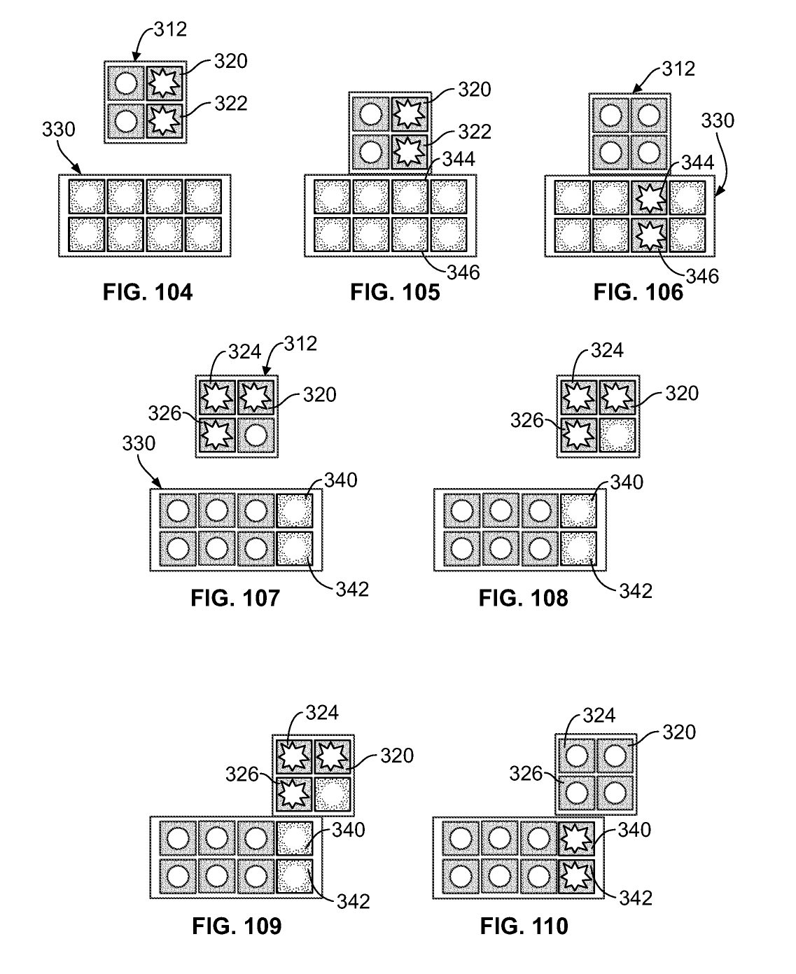

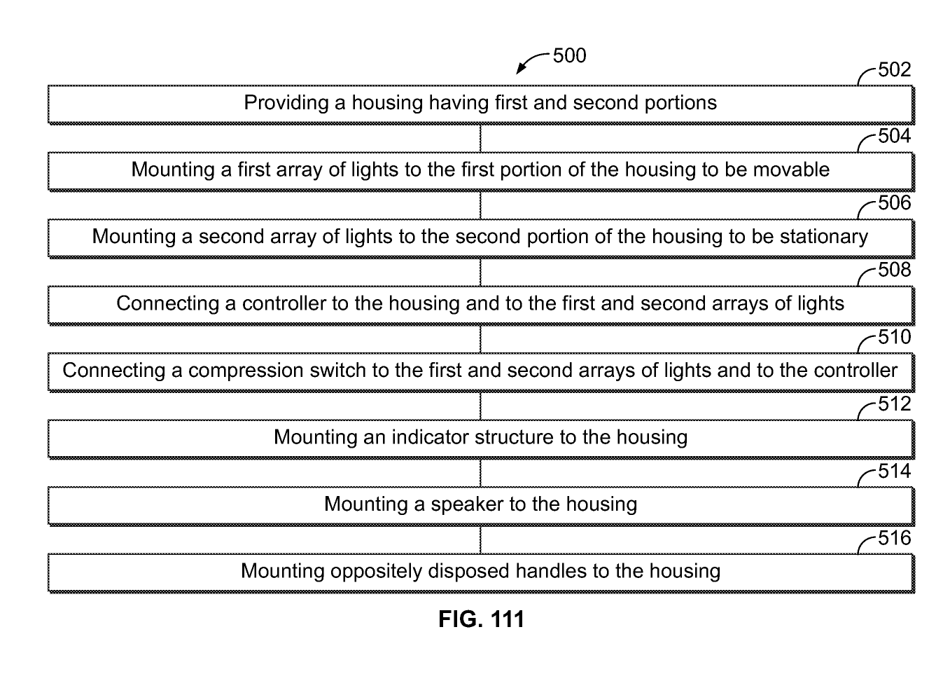

A small square bomb operates as expected as shown in FIGS. 101-103, where the bomb is formed by the light source 320 of the puzzle piece array of lights 312 and the puzzle space array of lights 330 are all illuminated, except for the light source 344. There is no obstacle for the bomb so that upon alignment and transfer, the bomb turns the light source 344 dark. A rectangle bomb consisting of the light sources 320, 322, FIG. 104, also operates as expected as shown in FIGS. 105-106. With no obstacles, after alignment and transfer the light sources 344, 346 go from illuminated to dark.

When there are only two illuminated light sources 340, 342, FIG. 107, to darken and an angle bomb formed by the three light sources 320, 324, 326, the array of lights 312 may be aligned to overhang the array of lights 330 so that the light sources 324, 326 are aligned with the lights sources 340, 342, FIG. 108. Causing a transfer, as shown in FIG. 109, completes the darkening of the array of lights 330. The overhanging bomb, the light source 320, is ignored because as an extra bomb it is not needed.

As a general rule, the apparatus may be programmed with puzzle pairs, pieces and spaces, such that the same puzzle piece light pattern and puzzle space light pattern will appear in pairs. As each round is handled successfully, another pair appears. An easy version of the game has pairs that do not require the player to rotate the puzzle piece. Harder rounds may always require rotation of the puzzle piece. Alternatively, the game apparatus may be programmed to provide a random light pattern and a code that considers the pattern and creates its own puzzle space.

In the alternative, the various sequences or patterns may be altered from those disclosed by mixing those provided and/or creating new patterns and sequences. Also, point scores, the number of failures allowed before a game ends, illumination durations and tempos may all be changed as desired, such as by making each round more difficult. An objective of the invention is to create and maintain a high level of concentration and intensity to excite players of the game apparatus.

The present invention also includes a method 500 for making a puzzle game apparatus, the steps of the method including providing a housing having first and second portions 502, each portion being structurally arranged to translate relative to one another along a longitudinal axis of the housing, mounting a first array of lights to the first portion of the housing 504 to enable the first array of lights to rotate around the longitudinal axis of the housing and to rotate around an axis perpendicular to the longitudinal axis, mounting a second array of lights to the second. portion of the housing 506, connecting a controller to the housing and to the first and second arrays of lights 508 for selecting from a multiplicity of varying light patterns for display on the first and second arrays of lights, including a first predetermined light pattern to appear on the first array of lights and a second predetermined pattern to appear on the second array of lights, connecting a compression switch to the first and second arrays of lights and to the controller 510 for activation when the patterns of the first and second arrays of lights display the first and the second predetermined patterns, mounting an indicator structure to the. housing 512 and operatively connecting the indicator structure to the controller and the compression switch, mounting a speaker to the housing 514, and mounting oppositely disposed handles to the housing 516.

The puzzle game apparatus disclosed in detail above has great play value, is fun to play because of the concentration and intensity required, and is easy to operate in a safe manner, and yet the game apparatus has a robust, but simple structure, that may be produced at a reasonable cost.

From the foregoing, it can be seen that there has been provided features for improved game apparatus and a disclosure for methods of the making the apparatus. While particular embodiments of the present invention have been shown and described in detail, it will be obvious to those skilled in the art that changes and modifications may be made without departing from the invention in its broader aspects. Therefore, the aim is to cover all such changes and modifications as fall within the true spirit and scope of the invention. The matters set forth in the foregoing description and accompanying drawings are offered by way of illustrations only and not as limitations. The actual scope of the invention is to be defined by the subsequent claims when viewed in their proper perspective based on the prior art.

What is claimed is:

1. A light pattern game apparatus comprising:
a housing having first and second portions;
a first array of lights mounted to the first portion of the housing;
a second array of lights mounted to the second portion of the housing;
a controller connected to the housing and to the first and second arrays of lights for selecting from a multiplicity of varying patterns for display on the first and second arrays of lights, including a first predetermined light pattern to appear on the first array of lights and a second predetermined pattern to appear on the second array of lights;
a compression switch mounted to the housing operatively connected to the first and second arrays of lights and to the controller for activation when the patterns of the first and second arrays of lights respectively display the first and the second predetermined patterns; and
an indicator structure mounted to the housing and operatively connected to the controller and the compression switch for informing a game player whether the compression switch is activated when the first and the second predetermined patterns are displayed on the first and second arrays of lights.

2. The game apparatus of claim 1 wherein:
the first array of lights is mounted to the first portion of the housing to enable rotation around a longitudinal axis of the housing, rotation around an axis perpendicular to the longitudinal axis and translation parallel to the longitudinal axis.

3. The game apparatus of claim 1, wherein:
the second array of lights is fixedly mounted to the second portion of the housing.

4. The game apparatus of claim 1, wherein:
the first portion of the housing is both rotatable and translatable relative to the second portion of the housing.

5. The game apparatus of claim 1, wherein:
the compression switch is activated by the relative movement of the first and the second housing portions.

6. The game apparatus of claim 1, wherein:
the housing is generally cylindrical in shape and includes oppositely disposed handles.

7. The game apparatus of claim 1, wherein:
the indicator structure includes the controller and the first and second arrays of lights for extinguishing predetermined lights of the first array of lights and illuminating or extinguishing predetermined lights of the second array of lights.

8. The game apparatus of claim 1, wherein:
the first array of lights is mounted to the first portion of the housing to enable rotation around a longitudinal axis of the housing, rotation around an axis perpendicular to the longitudinal axis, and translation parallel to the longitudinal axis; and
the second array of lights is fixedly mounted to the second portion of the housing.

9. The game apparatus of claim 8, wherein:
the housing is generally cylindrical in shape and includes oppositely disposed handles.

10. The game apparatus of claim 9, wherein:
the first portion of the housing is both rotatable and translatable relative to the second portion of the housing.

11. The game apparatus of claim 10, wherein:
a compression switch is mounted with the housing and is activated by relative movement of the first and second housing portions.

12. The game apparatus of claim 11, wherein:
the indicator structure includes the controller, and the first and second arrays of lights for extinguishing predetermined lights of the first array of lights and illuminating or extinguishing predetermined lights of the second array of lights.

13. A puzzle game apparatus comprising:
a housing having first and second portions, each portion being structurally arranged to move relative to each other along a longitudinal axis of the housing;
a first array of lights mounted to the first portion of the housing, the first array of lights being rotatable around the longitudinal axis of the housing and rotatable around an axis perpendicular to the longitudinal axis;
a second array of lights mounted to the second portion of the housing;
a controller connected to the housing and to the first and second arrays of lights for selecting from a multiplicity of varying light patterns for display on the first and second arrays of lights, including a first predetermined light pattern to appear on the first array of lights and a second predetermined pattern to appear on the second array of lights;
a compression switch mounted to the housing operatively connected to the first and second arrays of lights and to the controller for activation when the patterns of the first and second arrays of lights display the first and the second predetermined patterns; and
an indicator structure mounted to the housing and operatively connected to the controller and the compression switch for informing a game player whether the compression switch is activated when the first and the second predetermined patterns are displayed. on the first and second arrays of lights.

14. The game apparatus of claim 13, wherein:
the indicator structure includes a speaker operatively connected to the controller and the compression switch.

15. The game apparatus of claim 14, wherein:
the housing includes oppositely disposed mounted handles.

16. A method for making a puzzle game apparatus, the steps of the method comprising:
providing a housing having first and second portions, each portion being structurally arranged to translate relative to one another along a longitudinal axis of the housing;
mounting a first array of lights to the first portion of the housing to enable the first array of lights to rotate around the longitudinal axis of the housing and to rotate around an axis perpendicular to the longitudinal axis;
mounting a second array of lights to the second portion of the housing;
connecting a controller to the housing and to the first and second arrays of lights for selecting from a multiplicity of varying light patterns for display on the first and second arrays of lights, including a first predetermined light pattern to appear on the first array of lights and a second predetermined pattern to appear on the second array of lights;
connecting a compression switch to the first and second arrays of lights and to the controller for activation when the patterns of the first and second arrays of lights display the first and the second predetermined patterns; and
mounting, an indicator structure to the housing and operatively connecting the indicator structure to the controller and the compression switch.

17. The method of claim 16, including the step of:
mounting a speaker to the housing.

18. The method of claim 16, including the step of:
mounting oppositely disposed handles to the housing.

19. The method of claim 16, wherein:
the second array of lights is fixedly mounted to the second portion of the housing.

20. The method of claim 19, including the steps of:
mounting a speaker to the housing; and
mounting oppositely disposed handles to the housing; and wherein
the second array of lights is fixedly mounted to the second portion of the housing.
